(19) United States
(12) Patent Application Publication
(10) Pub. No.: US 2021/0313482 A1
(43) Pub. Date: Oct. 7, 2021

(54) LIGHT REDIRECTING FILM HAVING STRAY-LIGHT MITIGATION PROPERTIES USEFUL WITH SOLAR MODULES

(71) Applicant: 3M INNOVATIVE PROPERTIES COMPANY, St. Paul, MN (US)

(72) Inventor: Mark B. O'Neill, Stillwater, MN (US)

(21) Appl. No.: 17/250,597

(22) PCT Filed: Aug. 27, 2019
(86) PCT No.: PCT/IB2019/057218

§ 371 Date: Feb. 8, 2021

Related U.S. Application Data
(60) Provisional application No. 62/725,712, filed on Aug. 31, 2018.

(51) Int. Cl. H01L 31/054; G02B 5/02; G02B 19/00; H01L 31/05

(52) U.S. Cl. CPC H01L 31/0547; H01L 31/0508; G02B 19/0042; G02B 5/0231

(57) ABSTRACT

The present disclosure relates to reflective microstructured films having stray-light mitigation properties, and their use in solar modules.

The present disclosure relates to reflective microstructured films having stray-light mitigation properties, and their use in solar modules.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from photovoltaic systems. The rising demand for solar power has been accompanied by a rising demand for devices and material capable of fulfilling the requirements for these applications.

Harnessing sunlight may be accomplished by the use of photovoltaic (PV) cells (also referred to as solar cells), which are used for photoelectric conversion (e.g., silicon photovoltaic cells). PV cells are relatively small in size and typically combined into a physically integrated PV module (or solar module) having a correspondingly greater power output. PV modules are generally formed from two or more “strings” of PV cells, with each string consisting of a plurality of PV cells arranged in a row and are typically electrically connected in series using tinned flat copper wires (also known as electrical connectors, tabbing ribbons, or bus wires). These electrical connectors are typically adhered to the PV cells by a soldering process. PV modules typically further comprise the PV cell(s) surrounded by an encapsulant, such as generally described in U.S. Patent Publication No. 2008/0078445 (Patel et al.), the teachings of which are incorporated herein by reference. In some constructions, the PV module includes encapsulant on both sides of the PV cell(s). A panel of glass (or other suitable polymeric material) is bonded to each of the opposing, front and back sides, respectively, of the encapsulant. The panels are transparent to solar radiation and are typically referred to as the front-side layer and the backside layer (or backsheet). The front-side layer and the backsheet may be made of the same or a different material. The encapsulant is a light-transparent polymer material that encapsulates the PV cells and also is bonded to the front-side layer and the backsheet so as to physically seal off the PV cells. This laminated construction provides mechanical support for the PV cells and also protects them against damage due to environmental factors such as wind, snow and ice. The PV module is typically fit into a metal frame, with a sealant covering the edges of the module engaged by the metal frame. The metal frame protects the edges of the module, provides additional mechanical strength, and facilitates combining it with other modules so as to form a larger array or solar panel that can be mounted to a suitable support that holds the modules together at a desired angle appropriate to maximize reception of solar radiation.

The art of making PV cells and combining them to make laminated modules is exemplified by the following U.S. Pat. No. 4,751,191 (Gonsiorawski et al.); U.S. Pat. No. 5,074,920 (Gonsiorawski et al.); U.S. Pat. No. 5,118,362 (St. Angelo et al.); U.S. Pat. No. 5,178,685 (Borenstein et al.); U.S. Pat. No. 5,320,684 (Amick et al.); and U.S. Pat. No. 5,478,402 (Hanoka).

With many PV module designs, the tabbing ribbons represent an inactive shading region (i.e., area in which incident light is not absorbed for photovoltaic or photoelectric conversion). The total active surface area (i.e., the total area in which incident light is use for photovoltaic or photoelectric conversion) is thus less than 100% of the original photovoltaic cell area due to the presence of these inactive areas. Consequently, an increase in the number or width of the tabbing ribbons decreases the amount of current that can be generated by the PV module because of the increase in inactive shaded area.

To address the above concerns, PCT Publication No. WO 2013/148149 (Chen et al.), the teachings of which are incorporated herein by reference, discloses a light directing medium, in the form of a strip of microstructured film carrying a light reflective layer, applied over the tabbing ribbons. The light directing medium directs light that would otherwise be incident on an inactive area onto an active area. More particularly, the light directing medium redirects the incident light into angles that totally internally reflect (TIR) from the front-side layer; the TIR light subsequently reflects onto an active PV cell area to produce electricity. In this way, the total power output of the PV module can be increased, especially under circumstances where an arrangement of the microstructures relative to a position of the sun is relatively constant over the course of the day. However, where asymmetrical conditions are created by the PV module installation relative to a position of the sun (e.g., a non-tracking PV module installation, portrait vs. landscape orientation, etc.), light reflection caused by the microstructured film may, under certain conditions, undesirably lead to some of the reflected light escaping from the PV module.

Ideally, light impinging on the LRF in a PV module is discretely reflected at angles larger than the critical angle of the outer surface. This light undergoes TIR to reflect back to the silicon wafers for absorption to produce electricity. The normal incidence beam can undergo a total deviation of more than 17° before TIR is no longer accomplished (this is the internal angle after refraction at the air-module interface). We have observed, however, that stray light reflects from PV modules having LRF during certain time periods causing glare and undesirable aesthetic effects. The magnitude and nature of the stray light depends on the latitude of the installation, orientation of the PV module, tilt of the module, time of day and seasonally.

In light of the above, there is a need for a light redirecting film that reduces the presence of stray light.

### SUMMARY

Some aspects of the present disclosure are directed toward a light redirecting film (LRF) article that reduces the generation of stray light. There are various ways in which an LRF article may be able to reduce stray light.

One way, for example, is to diffuse the light that escapes the solar module after being reflected by the LRF. In one embodiment, such diffusion is achieved through modification of the LRF prism facets. Typically, the diffusion spreads the beam reflected on the prism surface such that normal axis light is still trapped by total internal reflection while off-axis light that escapes the PV module is distributed over a wider angular range. This diffusion reduces the irradiance of the escaped light decreasing the undesirable effects of the escaped light.

The inventors envision various methodologies that result in light redirecting films with decreased stray light. For example, the LRF article may comprise LRF having microstructures with curved facets. In other embodiments, the surface of the microstructures may have roughness, be textured, or have certain features that help diffuse reflected light. The LRF prisms may have one or more of these surface topographies and the roughness, texture, or features maybe random, pseudo-random, or structured (having certain order or periodicity). Moreover, the modifications to the facet surface may be in the form of depressions or indentations, or in the form of elevated features, such as bumps, peaks, etc.

In yet other embodiments, the LRF prisms may have either a height that varies along the longitudinal axis of the prism, or may have a ridgeline defined by the prism peak that does not follow a straight line. See, for example, FIG. 2.

### LRF Articles

The following text describes the core or basic LRF and LRF articles which, through modification, can produce LRF or LRF articles having decreased stray light generation.

In general an LRF article includes a light redirecting film having a width and a length, the length being longer than the width, with the length defining a longitudinal axis. The light redirecting film typically comprises a base layer, an ordered arrangement of a plurality of microstructures, and a reflective layer. The plurality of microstructures project from the base layer. Further, each of the microstructures extends (preferably continuously, but continuity is not an absolute requirement) along the base layer to define a corresponding primary axis. Throughout the instant disclosure, when a microstructure continuously extends along the base layer across the width of the light redirecting film to define a corresponding primary axis, the primary axis is defined by the elongated shape of the microstructure (along the peak (e.g., 60 or 60′, see, for instance, FIG. 1A). In general, the film defines an X-Y plane and the microstructures raise or protrude in the Z direction, out of the X-Y plane. The primary axis of at least one (preferably the majority) of the microstructures is oblique with respect to the longitudinal axis (that is, the primary axis is not parallel to the longitudinal axis of the film). Finally, the reflective layer is disposed over the microstructures opposite the base layer. With this construction, the obliquely arranged, reflectorized microstructure(s) will reflect light in a unique manner relative to the longitudinal axis that differs from aligned, unbiased arrangement (that is, an arrangement in which the primary axis of the microstructure is parallel to the longitudinal axis of the film). In some embodiments, a majority or all of the microstructures are arranged such that the corresponding primary axes are all oblique with respect to the longitudinal axis. In other embodiments, the longitudinal axis and the primary axis of at least one of the microstructures, optionally a majority or all of the microstructures, forms a bias angle with respect to the longitudinal axis in the range of 1°-90°, alternative in the range of 20°-70°, alternative in the range 70°-90°. In yet other embodiments, the light redirecting film article further includes an adhesive layer disposed on the base layer opposite the microstructures and in other embodiments the film further comprises a liner adjacent the adhesive layer as an outermost layer.

Other aspects of the present disclosure are directed toward a PV module including a plurality of PV cells electrically connected by tabbing ribbons. Further, a light redirecting film article having light redirecting film that has been modified to reduce stray light is disposed over at least a portion of at least one of the tabbing ribbons. In other embodiments, the modified light redirecting film may substitute for a tabbing ribbon. In other embodiments, the modified light redirecting film may fill the space between or surrounding the PV cells in the PV module, or any other area that is not part of a PV cell capable of converting incident light into electricity. The light redirecting film article can have any of the constructions described above. In other embodiments, the PV module can have the light redirecting film article placed on one, all, or any combination of the locations described above (over a portion of some tabbing ribbons, replacing one or more tabbing ribbons, and/or on areas not able to covert incident light into electricity). A front-side layer (e.g., glass) is located over the PV cells and the light redirecting film article. The light redirecting film article can render the PV module to be orientation independent, exhibiting relatively equivalent annual efficiency performance with respect to electric power generation in a stationary (i.e., non-tracking) installation independent of landscape orientation or portrait orientation. In other embodiments, the light redirecting film article can enable the PV module to have superior performance in portrait orientation in a stationary (i.e., non-tracking) installation. In other embodiments, the light redirecting film article can enable the PV module to have superior performance in landscape or portrait orientation in a single axis tracking installation.

All scientific and technical terms used herein have meanings commonly used in the art unless otherwise specified. The definitions provided herein are to facilitate understanding of certain terms used frequently in this application and are not meant to exclude a reasonable interpretation of those terms in the context of the present disclosure.

Unless otherwise indicated, all numbers in the description and the claims expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviations found in their respective testing measurements.

The recitation of numerical ranges by endpoints includes all numbers subsumed within that range (e.g. a range from 1 to 5 includes, for instance, 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

As used herein, the term “ordered arrangement” when used to describe microstructural elements, especially a plurality of microstructures, means an imparted pattern different from natural surface roughness or other natural features, where the arrangement can be continuous or discontinuous, can include a repeating pattern, a non-repeating pattern, a random pattern, etc.

As used herein, the term “microstructure” means the configuration of elements wherein at least 2 dimensions of the element are microscopic. The topical and/or cross-sectional view of the element must be microscopic.

As used herein, the term “microscopic” refers to element of small enough dimension so as to require an optic aid to the naked eye when viewed from any plane of view to determine its shape. One criterion is found in Modern Optic Engineering by W. J. Smith, McGraw-Hill, 1966, pages 104-105 whereby visual acuity, “ . . . is defined and measured in terms of the angular size of the smallest character that can be recognized.” Normal visual acuity is considered to be when the smallest recognizable letter subtends an angular height of 5 minutes of arc of the retina. At a typical working distance of 250 mm (10 inches), this yields a lateral dimension of 0.36 mm (0.0145 inch) for this object.

### BRIEF DESCRIPTION OF THE DRAWINGS

FIG. 1A is a simplified top plan view of a light redirecting film article in accordance with principles of the present disclosure;

FIG. 1B is an enlarged cross-sectional view of a portion of the article of FIG. 1A, taken along the line 1B-1B;

FIG. 1C is an enlarged cross-sectional view of a portion of the article of FIG. 1A, taken along the line 1C-1C;

FIG. 2 shows schematically the ridgeline of a prism of a light redirecting film useful with articles of the present disclosure not following a straight line (top portion) and the height of the peak not being constant along the longitudinal axis of the prism (bottom portion);

FIG. 3 is a simplified side view of a portion of another light redirecting film useful with articles of the present disclosure;

FIG. 4 is an enlarged cross-sectional view of a portion of another light redirecting film article in accordance with principles of the present disclosure;

FIG. 5 is a perspective view of another light redirecting film article in accordance with principles of the present disclosure and provided in a rolled form;

FIG. 6A is a simplified cross-sectional view of a portion of a PV module in accordance with principles of the present disclosure;

FIG. 6B is a simplified cross-sectional view of a portion of a PV module in accordance with principles of the present disclosure;

FIG. 7A is a simplified top plan view of the PV module of FIG. 6A at an intermediate stage of manufacture;

FIG. 7B is a simplified top plan view of the PV module of FIG. 7A at a later stage of manufacture;

FIG. 8 is a schematic side view of a portion of a conventional PV module;

FIG. 9A is a simplified top view of the conventional PV module of FIG. 8 in a landscape orientation;

FIG. 9B is a simplified top view of the conventional PV module of FIG. 8 in a portrait orientation;

FIG. 10 is a simplified top plan view illustrating manufacture of a PV module in accordance with principles of the present disclosure;

FIG. 11 shows a cross sectional view of a microstructured element of an LRF according to the present disclosure, in which a facet is curved;

FIG. 12 shows an example of depressions and protrusions on the surface of a prism facet;

FIG. 13 shows microstructures resulting from a depth function with 100% amplitude modulation and 180° phase difference;

FIG. 14 shows microstructures resulting from a lateral function with 100% amplitude modulation and 0° phase difference;

FIG. 15 shows an embodiment of an LRF having undulating microstructures;

FIG. 16 shows another embodiment of an LRF having undulating microstructures;

FIGS. 17A, 17B, and 17C show representative grooves that can be used in the manufacture of LRF microstructures;

FIG. 18 shows a conoscopic plot from a ray trace simulation depicting input angles for light that escapes from a photovoltaic module over the course of a year;

FIG. 19 shows a conoscopic plot depicting the simulated reflected angles of light escaping from a photovoltaic module with 10° module tilt on June 21 at 9:21 a.m.;

FIG. 20A shows a conoscopic image from a ray tracing simulation depicting input angles for light reflected from a light redirecting film featuring flat prisms with chaotic height variations;

FIG. 20B shows a conoscopic image created from measurements of an optical measurement system of a sample film featuring flat prisms with chaotic height variations;

FIG. 21A shows a conoscopic image from a ray tracing simulation depicting input angles for light reflected from a light redirecting film featuring curved prisms with chaotic height variations;

FIG. 21B shows a conoscopic image created from measurements of an optical measurement system of a sample film featuring curved prisms with chaotic height variations;

FIG. 22A shows a conoscopic image from a ray tracing simulation depicting input angles for light reflected from a light redirecting film featuring curved prisms;

FIG. 22B shows a conoscopic image created from measurements of an optical measurement system of a sample film featuring curved prisms; and

FIG. 23 shows a conoscopic image from a ray tracing simulation depicting input angles for light reflected from a light redirecting film featuring curved prisms with a 45-degree bias angle.

### DETAILED DESCRIPTION

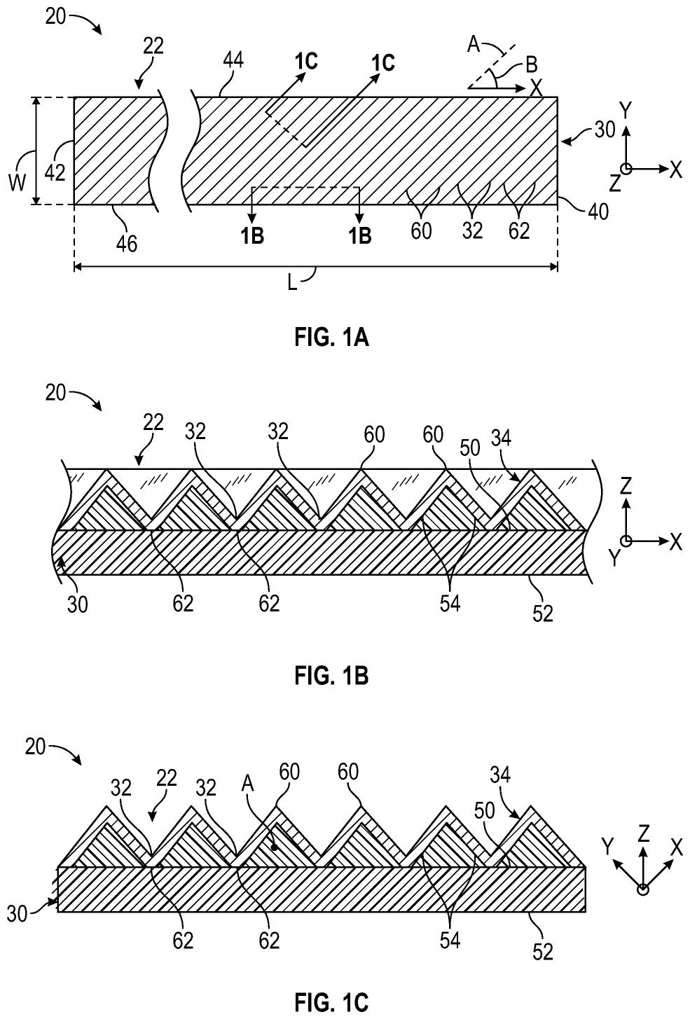

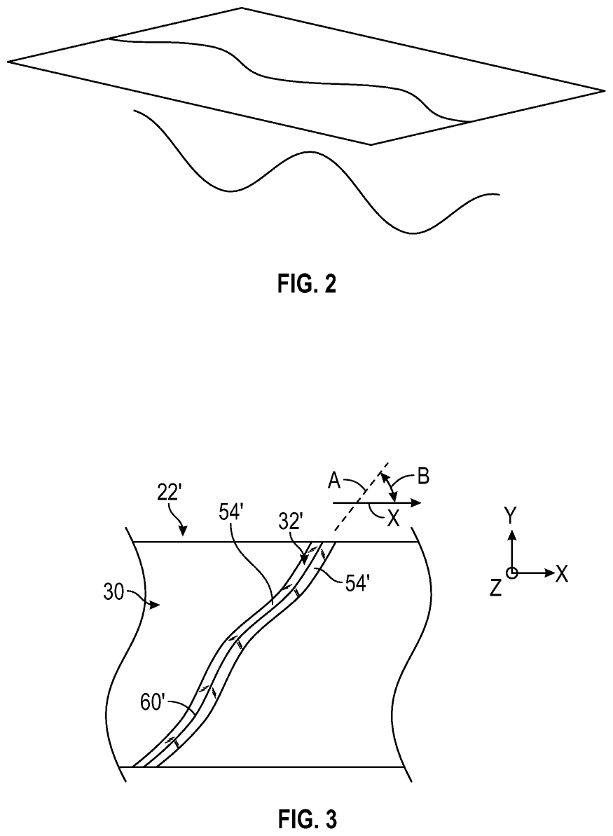

The present disclosure is directed to light redirecting films having microstructures that reduce stray light and light redirecting film articles comprising those light redirecting films. This disclosure will refer to those light redirecting films or light redirecting film articles that reduce stray light as modified LRFs or modified LRF articles, or simply LRFs or LRF articles. Throughout this disclosure the terms prisms and microstructures will be used interchangeably to refer to the reflective elements of a light redirecting film (see FIG. 1A to FIG. 1C).

In general, one way of making LRFs of the present disclosure is to engrave a metal roll to form a microreplication tool, and then to use that tool to form the film. For instance, the surface of a roll of that type is created by cutting either a succession of adjacent individual grooves or, more commonly, by cutting a single helical groove (commonly referred to as a “thread cut”), into that surface, typically by using a diamond tool. Subsequently, a molten polymer, such as acrylate, may be extruded onto the microreplication tool and then removed. The film then has one surface that exhibits the opposite structure of the pattern on the microreplication tool.

### Curved Facets

In some embodiments, the LRF comprise prisms having a cross section comprising at least two sides, wherein at least one of the at least two sides comprises a curved surface defined by a radius of curvature. In prisms, these sides or surfaces when viewed in a cross-sectional view are sometimes called “facets”. In this disclosure the terms “sides” or “surfaces” are generally used to describe the sides of the microstructures, but these terms can be used interchangeably with “facets.” In addition, the peaks of the microstructures may be sharp or rounded. These LRF's having at least one curved facet are able to diffuse to a higher degree the reflected light compared to their counterparts that have “flat” facets. This property reduces the amount of stray light, which is one of the purposes of the present disclosure.

As mentioned above, in one embodiment, at least one surface of microstructures can be described as having a radius of curvature. In some embodiments, the radius of the curvature is the same for all of the curved surfaces. However, this is not necessarily the case in all embodiments. This radius of curvature is explained in FIG. 11, which shows a cross sectional view of a portion of one prism.

Angle theta1 in FIG. 11 is different from angle theta2 because the side shown in that figure is curved. The angular width of a curved line with a radius of curvature is the difference theta2 minus theta1, which herein is referred to as the angle of curvature. Ideally, parallel rays of light reflected from such a surface spread into a fan of rays with an angular width equal to twice the angle of curvature.

The effect of this radius of curvature is that incident light that is reflected by the facet of the microstructure and is not captured under TIR, is more divergent than would be with flat facets.

The inventors envision light redirecting films having microstructures that reduce stray light wherein the prism has one or more of the stray-light mitigation features disclosed in this application. For example, in some embodiments, the LRF prisms comprise at least one curved surface and at least one other stray-light mitigation feature described herein.

### Surface Features

In other embodiments, reduction of stray light is accomplished by the presence of roughness, textures, or other features on the surface of a facet that help diffuse reflected light. In this disclosure, the roughness, textures, or other features will be referred to as “features,” regardless of whether they are depressions (extending below the surface level of the facet) or protrusions (rising above the surface level of the facet). Examples of these features are shown in FIG. 12.

LRFs having these features can be manufactured by microreplication using a tool that has the surface features so that when the films are made from the tool, the films will have the inverse image of the features on the tool. That is, the protrusions on the tool surface will become depressions on the microreplicated film and depressions on the tool will become protrusions on the film. Alternatively, the film may be microreplicated with tools having no surface features and the features are imparted to the film after microreplication.

Thus, in some embodiments, the films can be made by fabricating a tool having a structured surface having the desired features, and microreplicating the surface to produce the optical film. In some embodiments, fabrication of the tool can involve electrodepositing a first layer of a metal under conditions that produce a first major surface with a relatively high average roughness, followed by covering up the first layer by electrodepositing a second layer of the same metal on the first layer, under conditions that produce a second major surface with a relatively lower average roughness, i.e., lower than that of the first major surface. The second major surface has a structured topography which, when replicated to form a structured major surface of an optical film, provides the film with a desired surface topography. Before microreplication, the second major surface of the tool may be further treated, e.g., coated with a thin layer of a different metal such as for purposes of passivation or protection, but such a coating, when present, is preferably thin enough to maintain substantially the same average roughness and topography as the second major surface of the second layer. By forming the structured surface using electrodeposition techniques rather than techniques that require cutting of a substrate with a diamond tool or the like, large area tool surfaces can be prepared in substantially less time and at reduced cost.

In some embodiments, the topography of the film/tool surface may possess a degree of irregularity or randomness in surface profile characterized by an ultra-low periodicity, i.e., a substantial absence of any significant periodicity peaks in a Fourier spectrum as a function of spatial frequency along each of a first and second orthogonal in-plane direction. In general, the film surface may comprise discernible features, e.g. in the form of distinct cavities and/or protrusions, and the features may be limited in size along two orthogonal in-plane directions. The size of a given structure may be expressed in terms of an equivalent circular diameter (ECD) in plain view, and the features may have an average ECD of less than 15 microns, or less than 10 microns, or in a range from 4 to 10 microns, or less than 1 micron, or down to 0.1 microns, for example. In some cases, the features may have a bimodal distribution of larger features in combination with smaller features. The features may be closely packed and irregularly or non-uniformly dispersed. In some cases, some, most, or substantially all of the features may be curved or comprise a rounded or otherwise curved base surface. In some cases, some of the features may be pyramidal in shape or otherwise defined by substantially flat facets. The features can in at least some cases be characterized by an aspect ratio of the depth or height of the structures divided by a characteristic transverse dimension, e.g. the ECD, of the structures. The film surface may comprise ridges, which may for example be formed at the junctions of adjacent closely-packed features. In such cases, a plan view of the film/tool surface (or of a representative portion thereof) may be characterized in terms of the total ridge length per unit area.

In some embodiments, any of the electroplating methods described above to provide surface features to the microreplicating tool can be used to provide features on the facet surfaces of the microstructures on the light redirecting film itself.

In other embodiments, the surface features can be provided by the presence of beads at or near the surface of the film. For example, the LRF may have a layer of microscopic beads adhered to, or imbedded on, the facet surface, and the refraction of light at the bead surfaces may operate to provide the light diffusion characteristics of the film to reduce stray light.

In yet other embodiments, the surface features on the facet of the microstructures can be provided by spraying a material that adheres to the surface, such as, an aerosol adhesive, for example, an acrylate adhesive. The spraying can be carried out either before or after the reflective layer of the LRF is applied to the resin microstructures, preferably before the reflective layer is applied.

### Non-Linear Microstructures

As mentioned above, one way of manufacturing LRF is by using thread cutting, where a single, continuous groove is cut on a microreplicating tool (also known as a roll) while a diamond tool is moved in a direction transverse to the turning tool. Subsequently, the tool is used to create a film with a mirror image of the of the surface of the tool. For microstructures having a constant pitch, the diamond tool may move at a constant velocity. However, in other embodiments, the diamond turning machine is controlled to handle independently the depth that the diamond tool penetrates the microreplicating roll, the horizontal and vertical angles that the tool makes to the roll, and the transverse velocity of the tool.

Accordingly, in some embodiments, a fast tool servo (FTS) is used to modify the path of the diamond tool during the cutting process to create different versions of replicating tools. A depth function, lateral function, angular function or a combination of these functions can alter the path of the cutting tool resulting in non-linear grooves. Examples of cutting paths with depth and lateral functions are shown in FIG. 12B.

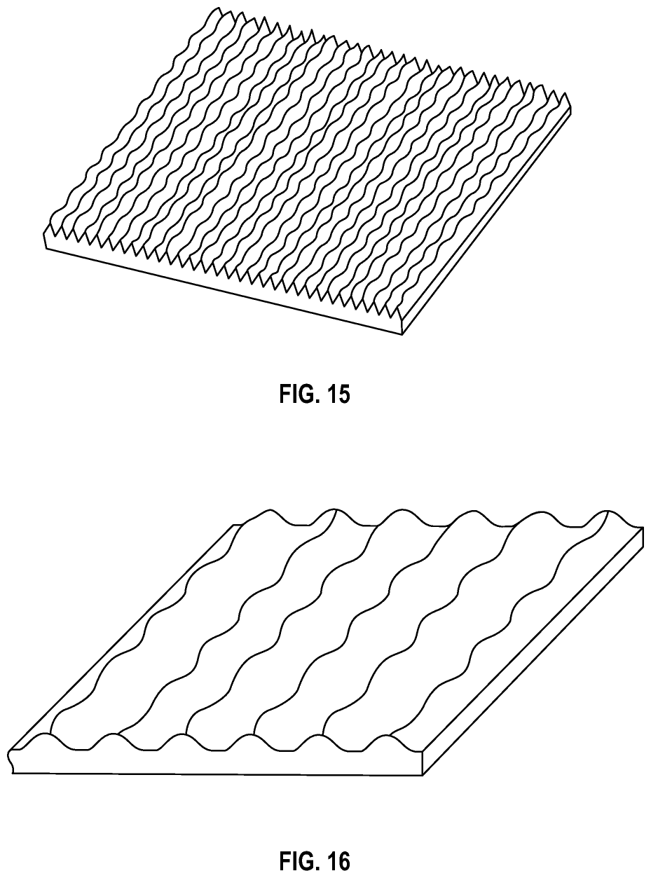

In some embodiments, the peaks of the microstructures of the LRF do not form a straight line, such as in FIG. 15. Instead the heights of the peaks of the microstructures vary continuously along their lengths (longitudinal axis). Similarly, the depths of the valleys between the peaks vary continuously. That is, the distances from the peak lines and/or the valley lines of the structures to the flat plane that forms the basis of the microstructure are continuously varying. In general, the actual heights of the microstructures, may vary between 70% and 130% and more preferably between 90-110% of the nominal or average height of the structures.

FIG. 16 shows an alternative embodiment of an LRF, in which the microstructures have rounded peaks and valleys rather than the sharp peaks and valleys shown in FIG. 15. In another embodiment, the variation in the height of the microstructures may follow a pattern or may be random or pseudo-random, rather than be smoothly varying as shown in FIGS. 15 and 16.

In other embodiments, the LRF are manufactured from microreplicating tools that have been made using a fly-cutting technique. Fly-cutting typically refers to the use of a cutting element, such as a diamond, that is mounted on or incorporated into a shank or tool holder that is positioned at the periphery of a rotatable head or hub, which is then positioned relative to the surface of the workpiece into which grooves or other features are to be machined. Fly-cutting is typically a discontinuous cutting operation, meaning that each cutting element is in contact with the workpiece for a period of time, and then is not in contact with the workpiece for a period of time during which the fly-cutting head is rotating that cutting element through the remaining portion of a circle until it again contacts the workpiece. Although a fly-cutting operation is typically discontinuous, the resulting groove segment or other surface feature formed in a workpiece by the fly-cutter may be continuous (formed by a succession of individual, but connected cuts, for example) or discontinuous (formed by disconnected cuts), as desired.

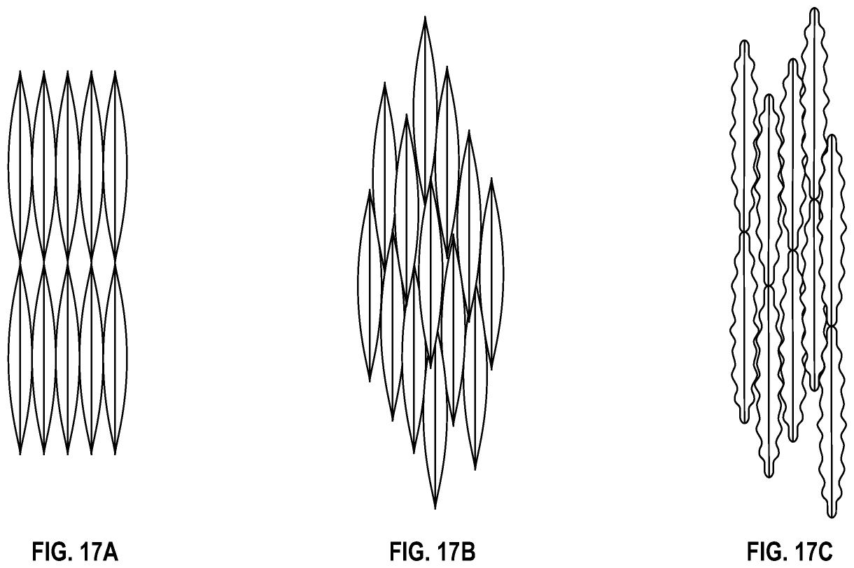

FIGS. 17A, 17B, and 17C show several representative illustrations of grooves or cuts that may be made on a replicating tool. The features shown in FIG. 17A generally represent individual grooves cut into a workpiece, each aligned with a previous groove so as to approximate a series of continuous linear grooves. The features shown in FIG. 17B generally represent individual grooves cut into a workpiece, in which the grooves are not aligned, and may overlap each other in the longitudinal direction of the groove or the transverse or lateral direction of the groove if it is desirable not to have any land area between grooves. The features shown in FIG. 17C generally represent individual grooves cut into a workpiece, in which one or more actuators caused variations in the position or orientation of the cutting element, such as variations along the X axis. Once microreplicating tools having those cuts are made, then LRFs having microstructures with the inverse structured surface can be manufactured. Such LRFs have facets that diffuse reflected light and which decrease stray light.

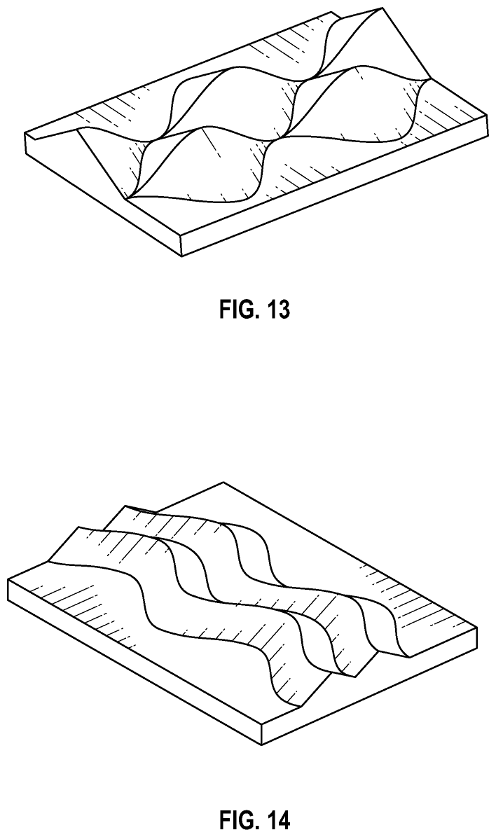

Other embodiments include prisms resulting from a depth function with 100% amplitude modulation and 180° phase difference, such as those shown in FIG. 13. The prism apex angle is a constant 120° while the facet surface normal direction sweeps through an arc.

Other embodiments prisms resulting from a lateral function with 100% amplitude modulation and 0° phase difference, such as those shown in FIG. 14. The prism apex angle is a constant 120° while the surface normal direction sweeps through an arc. Once replicated, the microstructures in films made from those tools are non-linear.

In some embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the ridgeline does not follow a straight line along the primary longitudinal axis.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline and the ridgeline does not follow a straight line along the primary longitudinal axis.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein at least one facet of the prism has at least one surface feature ranging in height from 0.1 microns to 5 microns.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the length of the light redirecting film defines a film longitudinal axis,
wherein the primary longitudinal axis of at least a portion of the microstructures is oblique with respect to the film longitudinal axis defining a non-zero bias angle.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,

wherein the length of the light redirecting film defines a film longitudinal axis, wherein the primary longitudinal axis of a first portion of the microstructures is oblique with respect to the film longitudinal axis defining a first bias angle, wherein the primary longitudinal axis of a second portion of the microstructures is oblique with respect to the film longitudinal axis defining a second bias angle, and wherein the first bias angle is not the same as the second bias angle.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein at least one facet of at least one microstructure is curved.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline,
   wherein at least one facet of the prism has at least one surface feature ranging from 0.1 microns to 5 microns.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline, and
   wherein the length of the light redirecting film defines a film longitudinal axis, wherein the primary longitudinal axis of at least a portion of the microstructures is oblique with respect to the film longitudinal axis defining a non-zero bias angle.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline, and
   wherein at least one facet of at least one microstructure is curved.

In other embodiments, the present disclosure is directed to a light redirecting film article comprising a light redirecting film, wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
   wherein at least one of the microstructures extends along the base layer to define a primary longitudinal axis,
   wherein at least one microstructure comprises a prism having a height and a peak,
   wherein the height of the prism is defined by the distance from the first major surface of the base layer to the peak of the prism,
   wherein the peak defines a ridgeline in the direction of the primary longitudinal axis,
   wherein the height of the prism is not constant along the ridgeline,
   wherein the ridgeline does not follow a straight line along the primary longitudinal axis,
   wherein the length of the light redirecting film defines a film longitudinal axis, wherein the primary longitudinal axis of at least a portion of the microstructures is oblique with respect to the film longitudinal axis defining a non-zero bias angle.

### Light Redirecting Films and Articles

The following text describes the core or basic LRF and LRF articles which, through modification, can produce LRF or LRF articles having decreased stray light generation.

One embodiment of a light redirecting film article 20 in accordance with principles of the present disclosure is shown in FIGS. 1A-1C. The light redirecting film article 20 comprises a light redirecting film 22 having a base layer 30, an ordered arrangement of a plurality of microstructures 32, and a reflective layer 34. As a point of reference, features of the microstructures 32 can be described with respect to a longitudinal axis of the light redirecting film 22. In this regard, the light redirecting film 22 can be provided as an elongated strip having or defining a length L and a width W. For example, in some embodiments, the strip of light redirecting film 22 terminates at opposing end edges 40, 42 and opposing side edges 44, 46. The length L of the light redirecting film 22 is defined as the linear distance between the opposing end edges 40, 42, and the width W as the linear distance between the opposing side edges 44, 46. The length L is greater than the width W (e.g., on the order of at least ten times greater). The longitudinal axis of the light redirecting film 22 is defined in the direction of the length L, and is identified as the “X-axis” in FIG. 1A. A lateral axis (or Y-axis in FIG. 1A) is defined in the direction of the width W. In some embodiments, the longitudinal (X) and lateral (Y) axes can also be viewed as the web (or machine) and cross-web axes or directions, respectively, in accordance with accepted film manufacture conventions.

As best shown in FIGS. 1B and 1C, in one embodiment of the light redirecting film article, the base layer 30 has opposing, first and second major faces 50, 52, and each of the microstructures 32 projects from the first major face 50 to a height (Z-axis) of 5-500 micrometers is some embodiments. A shape of each of the microstructures 32 can be substantially prismatic (e.g., within 10% of a true prism), for example the substantially triangular prism shape shown (e.g., a “roof” prism, although other prismatic shapes are also acceptable), and defines at least two facets 54. Throughout the instant disclosure, a “substantially triangular prism shape” refers to a prism shape having a cross-sectional area that is 90% to 110% of the area of largest inscribed triangle in the corresponding cross-sectional area of the prism. Regardless, a shape of each of the microstructures 32 terminates or defines a peak 60 opposite the base layer 30. In some embodiments, the peak 60 can define an apex angle of about 120 degrees (e.g., plus or minus 5 degrees) for the shape of the corresponding microstructure 32. While the peak 60 of each of the microstructures 32 is shown in FIGS. 1B and 1C as being a sharp corner for ease of illustration, in other embodiments, one or more of the peaks 60 can be rounded for reasons made clear below. The peaks 60 (and valleys 62 between immediately adjacent microstructures 32) are also generally illustrated in the simplified top view of FIG. 1A that otherwise reflects that the microstructures 32 extend continuously across the base layer 30 (it being understood that in the view of FIG. 1A, although the base layer 30 is generally identified, the base layer 30 is effectively “behind” the plurality of microstructures 32). In this embodiment, the microstructures extend continuously, but other embodiments do not necessarily need to meet this requirement.

The continuous, elongated shape establishes a primary axis A for each of the microstructures 32 (i.e., each individual microstructure has a primary axis). It will be understood that the primary axis A of any particular one of the microstructures 32 may or may not bisect a centroid of the corresponding cross-sectional shape at all locations along the particular microstructure 32. Where a cross-sectional shape of the particular microstructure 32 is substantially uniform (i.e., within 5% of a truly uniform arrangement) in complete extension across the base layer 30, the corresponding primary axis A will bisect the centroid of the cross-sectional shape at all locations along a length thereof. Conversely, where the cross-sectional shape is not substantially uniform in extension across the base layer 30 (as described in greater detail below), the corresponding primary axis A may not bisect the centroid of the cross-sectional shape at all locations. For example, FIG. 2 is a simplified top view of an alternative light redirecting film 22′, and generally illustrates another microstructure 32′ configuration in accordance with principles of the present disclosure. The microstructure 32′ has a “wavy” shape in extension across the base layer 30, with variations in one or more of the facets 54′ and the peak 60′. The primary axis A generated by the elongated shape of the microstructure 32′ is also identified, and is oblique with respect to the longitudinal axis X of the light redirecting film 22′. In more general terms, then, and returning to FIGS. 1A-1C, the primary axis A of any particular one of the microstructures 32 is a straight line that is a best fit with a centroid of the elongated shape in extension across the base layer 30.

The microstructures 32 can be substantially identical with one another (e.g., within 5% of a truly identical relationship) in terms of at least shape and orientation, such that all of the primary axes A are substantially parallel to one another (e.g., within 5% of a truly parallel relationship). Alternatively, in other embodiments, some of the microstructures 32 can vary from others of the microstructures 32 in terms of at least one of shape and orientation, such that one or more of the primary axes A may not be substantially parallel with one or more other primary axes A. Regardless, the primary axis A of at least one of the microstructures 32 is oblique with respect to the longitudinal axis X of the light redirecting film 22. In some embodiments, the primary axis A of at least a majority of the microstructures 32 provided with the light redirecting film 22 is oblique with respect to the longitudinal axis X; in yet other embodiments, the primary axis A of all of the microstructures 32 provided with the light redirecting film 22 is oblique with respect to the longitudinal axis X. Alternatively stated, the angle between the longitudinal axis X and the primary axis A of at least one of the microstructures 32 define a bias angle B, as shown in FIG. 2. The bias angle B is in the range of 1°-90°, alternatively in the range of 20°-70°, alternatively in the range of 70°-90°. It should be noted the bias angle B can be measured clockwise from the axis X or anti-clockwise from the axis X. The discussion throughout this application describes positive bias angles for simplicity. Bias angles of B, −B, (m*180°+B), and −(m*180°−B) where m is an integer are part of this disclosure. For example, a bias angle B of 80° can also be described as a bias angle B of −120°. In other embodiments, the bias angle B is about 45° (e.g., plus or minus 5°). In other embodiments, for example in embodiments in which the PV module is in the portrait orientation, the bias angle B is from 65° to 90°, or from 70° to 90°, or from 75° to 90°, or from 75° to 85°,or from 80° to 90°, or from 80° to 85°, or 74°, or 75°, or 76°, or 77°, or 78°, or 79°, or 80°, or 81°, or 82°, or 83°, or 84°, or 85°, or 86°, or 87°, or 88°, or 89°, or 90°. In some embodiments, the bias angle B about 82° (e.g., plus or minus 8°, or plus or minus 5°) or about 70°, with, for example, plus or minus 8°, or plus or minus 5°). In some embodiments, the primary axis A of at least a majority of the microstructures 32 provided with the light redirecting film 22 combine with the longitudinal axis X to define the bias angle B as described above; in yet other embodiments, the primary axis A of all of the microstructures 32 provided with the light redirecting film 22 combine with the longitudinal axis X to define the bias angle B as described above. In this regard, the bias angle B can be substantially identical (e.g., within 5% of a truly identical relationship) for each of the microstructures 32, or at least one of the microstructures 32 can establish the bias angle B that differs from the bias angle B of others of the microstructures 32 (with all the bias angles B being within the range(s) set forth above). As described below, the oblique or biased arrangement of one or more of the microstructures 32 relative to the longitudinal axis X renders the light redirecting film 22 well-suited for use with PV modules as described below.

The reflective layer 34 uniformly covers or forms an outer face of each of the microstructures 32. Thus, the reflective layer 34 mimics the shape of the microstructures 32, providing reflective surfaces (e.g., corresponding with the facets 54) that are arranged oblique or biased relative to the longitudinal axis X for at least some, optionally all, of the microstructures 32 commensurate with the descriptions above. The combination microstructure 32 and reflective layer 34 can be referred to as a “reflectorized microstructure” or “reflectorized prism” in some embodiments. Further, light redirecting films and articles of the present disclosure having one or more reflectorized microstructures with a primary axis A oblique to the longitudinal axis X as described above are also referred to as “biased angle light redirecting films”.

The base layer 30 comprises a material. In some embodiments base layer 30 comprises a polymer. In other embodiments, base layer 30 comprises a conductive material. A wide range of polymeric materials are suitable for preparing the base layer 30. Examples of suitable polymeric materials include cellulose acetate butyrate; cellulose acetate propionate; cellulose triacetate; poly(meth)acrylates such as polymethyl methacrylate; polyesters such as polyethylene terephthalate and polyethylene naphthalate; copolymers or blends based on naphthalene dicarboxylic acids; polyether sulfones; polyurethanes; polycarbonates; polyvinyl chloride; syndiotactic polystyrene; cyclic olefin copolymers; silicone-based materials; and polyolefins including polyethylene and polypropylene; and blends thereof. Particularly suitable polymeric materials for the base layer 30 are polyolefins and polyesters. A wide range of conductive materials are suitable for preparing base layer 30. Examples of suitable conductive materials include but are not limited to copper wires, copper foils, aluminum wire, aluminum foils, and polymers containing conductive particles.

In some embodiments, the microstructures 32 may comprise a polymeric material. In some embodiments, the polymeric material of the microstructures 32 is the same composition as the base layer 30. In other embodiments, the polymeric material of the microstructures 32 is different from that of the base layer 30. In some embodiments, the base layer 30 material is a polyester and the microstructure 32 material is a poly(meth)acrylate. In other embodiments, the microstructures 32 may also comprise conductive materials that are the same or different than the base layer 30.

The reflective layer 34 can assume various forms appropriate for reflecting light, such as metallic, inorganic materials or organic materials. In some embodiments, the reflective layer 34 is a mirror coating. The reflective layer 34 can provide reflectivity of incident sunlight and thus can prevent some of the incident light from being incident on the polymer materials of the microstructures 32. Any desired reflective coating or mirror coating thickness can be used, for example on the order of 30-100 nm, optionally 35-60 nm. Some exemplary thicknesses are measured by optical density or percent transmission. Obviously, thicker coatings prevent more UV light from progressing to the microstructures 32. However, coatings or layers that are too thick may cause increased stress within the layer, leading to undesirable cracking. When a reflective metallic coating is used for the reflective layer 34, the coating is typically silver, aluminum, tin, tin alloys, or a combination thereof. Aluminum is more typical, but any suitable metal coating can be used. Generally, the metallic layer is coated by vapor deposition, using well understood procedures. The use of a metallic layer may require an additional coating to electrically insulate the light redirecting film article from electrical components in the PV module. Some exemplary inorganic materials include (but are not limited to) oxides (e.g., SiO₂, TiO₂, Al₂O₃, Ta₂O₅, etc.) and fluorides (e.g., MgF₂, LaF₃, AlF₃, etc.) that can be formed into alternating layers to provide a reflective interference coating suitable for use as a broadband reflector. Unlike metals, these layered reflectors may allow wavelengths non-beneficial to a PV cell, for example, to transmit. Some exemplary organic materials include (but are not limited to) acrylics and other polymers that may also be formed into layered interference coatings suitable for use as a broadband reflector. The organic materials can be modified with nanoparticles or used in combination with inorganic materials.

With embodiments in which the reflective layer 34 is provided as a metallic coating (and optionally with other constructions of the reflective layer 34), the microstructures 32 can be configured such that the corresponding peaks 60 are rounded, as alluded to above. One non-limiting example of the rounded peak construction is shown in FIG. 3. Depositing a layer of metal (i.e., the reflective layer 34) on rounded peaks is easier than depositing on sharp peaks. Also, when the peaks 60 are sharp (e.g., come to a point), it can be difficult to adequately cover the sharp peak with a layer of metal. This can, in turn, result in a “pinhole” at the peak 60 where little or no metal is present. These pinholes not only do not reflect light, but also may permit passage of sunlight to the polymeric material of the microstructure 32, possibly causing the microstructure 32 to degrade over time. With the optional rounded peak constructions, the peak 60 is easier to coat and the risk of pinholes is reduced or eliminated. Further, rounded peak films can be easy to handle and there are no sharp peaks present that might otherwise be vulnerable to damage during processing, shipping, converting or other handling steps.

Returning to FIGS. 1A-1C, in some embodiments, construction of the light redirecting film 22 generally entails imparting microstructures into a film. With these embodiments, the base layer 30 and the microstructures 32 comprise the same polymeric composition. In other embodiments, the microstructures 32 are prepared separately (e.g., as a microstructured layer) and laminated to the base layer 30. This lamination can be done using heat, a combination of heat and pressure, or through the use of an adhesive. In still other embodiments, the microstructures 32 are formed on the base layer 30 by means of crimping, knurling, embossing, extrusion or the like. In other embodiments, formation of the microstructures 32 apart from the base layer 30 can be done by microreplication.

One manufacturing technique conducive to microreplicating the microstructures 32 oblique to the longitudinal axis X (e.g., at a selected bias angle B) is to form the microstructures 32 with an appropriately constructed microreplication molding tool (e.g., a workpiece or roll) apart from the base layer 30. For example, a curable or molten polymeric material could be cast against the microreplication molding tool and allowed to cure or cool to form a microstructured layer in the molding tool. This layer, in the mold, could then be adhered to a polymeric film (e.g., the base layer 30) as described above. In a variation of this process, the molten or curable polymeric material in the microreplication molding tool could be contacted to a film (e.g., the base layer 30) and then cured or cooled. In the process of curing or cooling, the polymeric material in the microreplication molding tool can adhere to the film. Upon removal of the microreplication molding tool, the resultant construction comprises the base layer 30 and the projecting microstructures 32. In some embodiments, the microstructures 32 (or microstructured layer) are prepared from a radiation curable material, such as (meth)acrylate, and the molded material (e.g., (meth)acrylate) is cured by exposure to actinic radiation.

An appropriate microreplication molding tool can be formed by a fly-cutting system and method, examples of which are described in U.S. Pat. No. 8,443,704 (Burke et al.) and U.S. Publication No. 2009/0038450 (Campbell et al.), the entire teachings of each of which are incorporated herein by reference. Typically, in fly-cutting, a cutting element is used, such as a diamond, that is mounted on or incorporated into a shank or tool holder that is positioned at the periphery of a rotatable head or hub, which is then positioned relative to the surface of the workpiece into which grooves or other features are to be machined. Fly-cutting is a discontinuous cutting operation, meaning that each cutting element is in contact with the workpiece for a period of time, and then is not in contact with the workpiece for a period of time during which the fly-cutting head is rotating that cutting element through the remaining portion of a circle until it again contacts the workpiece. The techniques described in the '704 Patent and the '450 Publication can form microgrooves in a cylindrical workpiece or microreplication molding tool at an angle relative to a central axis of the cylinder; the microgrooves are then desirably arranged to generate biased or oblique microstructures relative to the longitudinal axis of a film traversing the cylinder in a tangential direction in forming some embodiments of the light redirecting films and articles of the present disclosure. The fly-cutting techniques (in which discrete cutting operations progressively or incrementally form complete microgrooves) may impart slight variations into one or more of the faces of the microgrooves along a length thereof; these variations will be imparted into the corresponding face or facet 54 of the microstructures 32 generated by the microgrooves, and in turn by the reflective layer 34 as applied to the microstructures 32. Light incident on the variations is diffused. As described in greater detail below, this optional feature may beneficially improve performance of the light redirecting film 22 as part of a PV module construction.

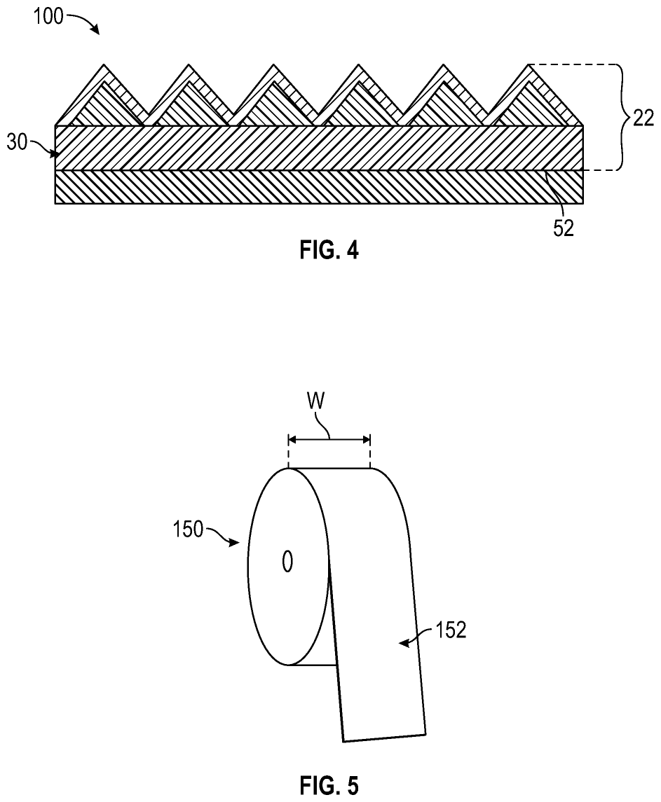

Another embodiment light redirecting film article 100 in accordance with principles of the present disclosure is shown in FIG. 4. The article 100 includes the light redirecting film 22 as described above along with an adhesive layer 102 applied (e.g., coated) to the second major face 52 of the base layer 30. The adhesive layer 102 can assume various forms. For example, the adhesive of the adhesive layer 102 can be a hot-melt adhesive such as an ethylene vinyl acetate polymer (EVA). Other types of suitable hot-melt adhesives include polyolefins. In other embodiments, the adhesive of the adhesive layer 102 is a pressure sensitive adhesive (PSA). Suitable types of PSAs include, but are not limited to, acrylates, silicones, polyisobutylenes, ureas, and combinations thereof. In some embodiments, the PSA is an acrylic or acrylate PSA. As used herein, the term “acrylic” or “acrylate” includes compounds having at least one of acrylic or methacrylic groups. Useful acrylic PSAs can be made, for example, by combining at least two different monomers (first and second monomers). Exemplary suitable first monomers include 2-methylbutyl acrylate, 2-ethylhexyl acrylate, isooctyl acrylate, lauryl acrylate, n-decyl acrylate, 4-methyl-2-pentyl acrylate, isoamyl acrylate, sec-butyl acrylate, and isononyl acrylate. Exemplary suitable second monomers include a (meth)acrylic acid (e.g., acrylic acid, methacrylic acid, itaconic acid, maleic acid, and fumaric acid), a (meth)acrylamide (e.g., acrylamide, methacrylamide, N-ethyl acrylamide, N-hydroxyethyl acrylamide, N-octyl acrylamide, N-t-butyl acrylamide, N,N-dimethyl acrylamide, N,Ndiethyl acrylamide, and N-ethyl-N-dihydroxyethyl acrylamide), a (meth)acrylate (e.g., 2-hydroxyethyl acrylate or methacrylate, cyclohexyl acrylate, t-butyl acrylate, or isobornyl acrylate), N-vinyl pyrrolidone, N-vinyl caprolactam, an alpha-olefin, a vinyl ether, an allyl ether, a styrenic monomer, or a maleate. Acrylic PSAs may also be made by including cross-linking agents in the formulation.

In some embodiments, the adhesive layer 102 can be formulated for optimal bonding to an expected end-use surface (e.g., tabbing ribbon of a PV module). Though not shown, the light redirecting film article 100 can further include a release liner as known in the art disposed on the adhesive layer 102 opposite the light redirecting film 22. Where provided, the release liner protects the adhesive layer 102 prior to application of the light redirecting film article 100 to a surface (i.e., the release liner is removed to expose the adhesive layer 102 for bonding to an intended end-use surface).

The light redirecting film articles 20, 100 of the present disclosure can be provided in various widths and lengths. In some embodiments, the light redirecting film article can be provided in a roll format, as represented by roll 150 in FIG. 5. The roll 150 can have various widths W appropriate for an expected end-use application. For example, with some embodiments useful with PV module end-use applications, the light redirecting film article 152 of the roll 150 can have a width W of not more than about 15.25 cm (6 inches) in some embodiments, or of not more than 7 mm in some embodiments. Commensurate with the above descriptions, the primary axis of the microstructures (not shown) provided with the light redirecting film article 152 are oblique with respect to the width W (and the wound length thereof).

### PV Modules

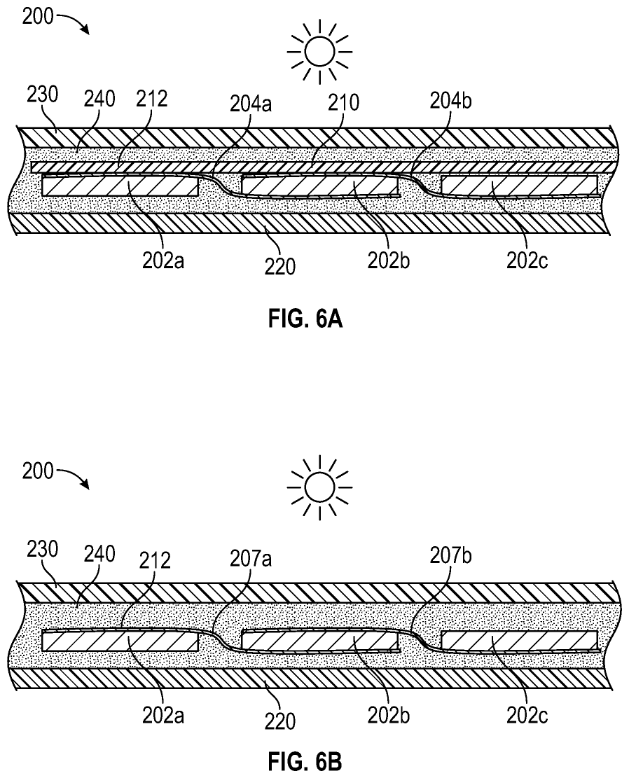

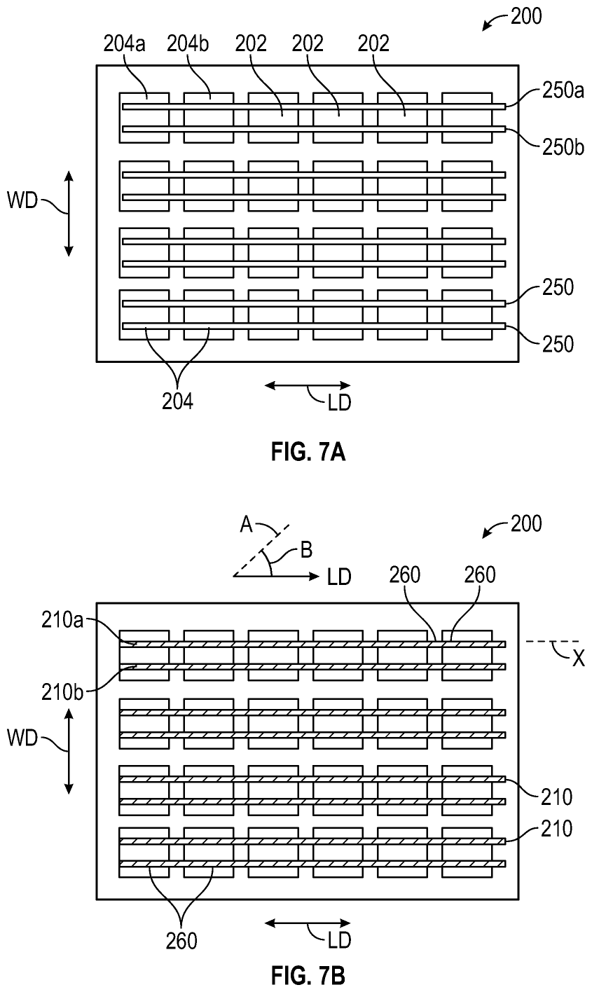

The light redirecting film articles of the present disclosure have multiple end use applications. In some embodiments, aspects of the present disclosure relate to use of the light redirecting films as part of a PV or solar module. For example, FIG. 6A is a cross-sectional view of a portion of one exemplary embodiment of a PV module 200 according to the present disclosure. The PV module 200 includes a plurality of rectangular PV cells 202a, 202b, 202c. Any PV cell format can be employed in the PV modules of the present disclosure (e.g., thin film photovoltaic cells, CuInSe₂ cells, a-Si cells, e-Si sells, and organic photovoltaic devices, among others). The light redirecting film article is shown as element 210. A metallization pattern is applied to the PV cells, most commonly by screen printing of silver inks. This pattern consists of an array of fine parallel gridlines, also known as fingers (not shown). Exemplary PV cells include those made substantially as illustrated and described in U.S. Pat. No. 4,751,191 (Gonsiorawski et al), U.S. Pat. No. 5,074,921 (Gonsiorawski et al), U.S. Pat. No. 5,118,362 (St. Angelo et al), U.S. Pat. No. 5,320,684 (Amick et al) and U.S. Pat. No. 5,478,402 (Hanoka), each of which is incorporated herein in its entirety. Electrical connectors or tabbing ribbons 204 (e.g., referenced generally in FIG. 7A; or in FIG. 6A and identified as 204a and 204b) are disposed over and typically soldered to the PV cells, to collect current from the fingers. In some embodiments, the electrical connectors 204 are provided in the form of coated (e.g., tinned) copper wires. Although not shown, it is to be understood that in some embodiments, each PV cell includes a rear contact on it rear surface.

In other embodiments, a light redirecting film article that includes a conductive substrate may replace the electrical connectors 204. In that embodiment the light redirecting film article is disposed over and soldered to the PV cells, to collect electrical current from the fingers while including light redirecting properties. For example, FIG. 6B is a cross-sectional view of a portion of one PV module 200 comprising such conductive light redirecting film article. The PV module 200 includes a plurality of rectangular PV cells 202a, 202b, 202c. As with FIG. 6A, any PV cell format can be employed in the PV modules of the present disclosure (e.g., thin film photovoltaic cells, CuInSe₂ cells, a-Si cells, e-Si sells, and organic photovoltaic devices, among others). The embodiment shown in FIG. 6B is similar to that in FIG. 6A, but in the embodiment of FIG. 6B, the tabbing ribbons identified as 207a and 207b comprise reflectorized microstructures and there is no light redirecting film as a separate element in the module. The upper surface of electrical connectors 207 are formed in a way as to contain microstructures as described in this disclosure thus performing both light redirecting and electrical connection functions.

A strip of a light redirecting film article 210 is applied over at least a portion of at least one of the electrical connectors 204 as described in greater detail below. The light redirecting film article 210 can have any of the forms described above. In some embodiments, the light redirecting film article 210 is bonded to the corresponding electrical connector 204 by an adhesive 212 (referenced generally). The adhesive 212 can be a component of the light redirecting film article 210 (e.g., the light redirecting film article 100 described above with respect to FIG. 4). In other embodiments, the adhesive 212 (e.g., thermally-activated adhesive, pressure sensitive adhesive, etc.) is applied over the electrical connector(s) 204 prior to application of the strip(s) of light redirecting film article 210. Though not shown, an additional strip of the light redirecting film article 210 can be applied to other regions of the PV module 200, such as between two or more of the PV cells, around the perimeter of one or more of the PV cells, etc.

The PV module 200 also includes a back protector member, often in the form of a backsheet 220. In some embodiments, the backsheet 220 is an electrically insulating material such as glass, a polymeric layer, a polymeric layer reinforced with reinforcing fibers (e.g., glass, ceramic or polymeric fibers), or a wood particle board. In some embodiments, the backsheet 220 includes a type of glass or quartz. The glass can be thermally tempered. Some exemplary glass materials include soda-lime-silica based glass. In other embodiments, the backsheet 220 is a polymeric film, including a multilayer polymer film One commercially available example of a backsheet is available under the trade designation 3M™ Scotchshield™ film from 3M Company of St. Paul, Minn. Other exemplary constructions of the backsheet 220 are those that include extruded PTFE. The backsheet 220 may be connected to a building material, such as a roofing membrane (e.g., in building integrated photovoltaics (BIPV)). In other embodiments, a portion of or the entire back protective member may include the function of the light redirecting film article such that when the PV cells are laminated with an encapsulant and a backsheet, any gaps between adjacent PV cells or at the perimeter of the PV cells reflect incident light, which can be used for energy generation. In this manner, any area on the module that receives incident light but without a PV cell may be better utilized for light collection.

In FIGS. 6A and 6B, overlying the PV cells 202a-202c is a generally planar light transmitting and electrically non-conducting front-side layer 230, which also provides support to the PV cells 202a-202c. In some embodiments, the front-side layer 230 includes a type of glass or quartz. The glass can be thermally tempered. Some exemplary glass materials include soda-lime-silica based glass. In some embodiments, the front-side layer 230 has a low iron content (e.g., less than about 0.10% total iron, more preferably less than about 0.08, 0.07 or 0.06% total iron) and/or an antireflection coating thereon to optimize light transmission. In other embodiments, the front-side layer 230 is a barrier layer. Some exemplary barrier layers are those described in, for example, U.S. Pat. No. 7,186,465 (Bright), U.S. Pat. No. 7,276,291 (Bright), U.S. Pat. No. 5,725,909 (Shaw et al), U.S. Pat. No. 6,231,939 (Shaw et al), U.S. Pat. No. 6,975,067 (McCormick et al), U.S. Pat. No. 6,203,898 (Kohler et al), U.S. Pat. No. 6,348,237 (Kohler et al), U.S. Pat. No. 7,018,713 (Padiyath et al), and U.S. Publication Nos. 2007/0020451 and 2004/0241454, all of which are incorporated herein by reference in their entirety.

In some embodiments, interposed between the backsheet 220 and the front-side layer 230 is an encapsulant 240 that surrounds the PV cells 202a-202c and the electrical connectors 204. The encapsulant is made of suitable light-transparent, electrically non-conducting material. Some exemplary encapsulants include curable thermosets, thermosettable fluoropolymers, acrylics, ethylene vinyl acetate (EVA), polyvinyl butryral (PVB), polyolefins, thermoplastic urethanes, clear polyvinylchloride, and ionmers. One exemplary commercially available polyolefin encapsulant is available under the trade designation PO8500™ from 3M Company of St. Paul, Minn. Both thermoplastic and thermoset polyolefin encapsulants can be used.

The encapsulant 240 can be provided in the form of discrete sheets that are positioned below and/or on top of the array of PV cells 202a-202c, with those components in turn being sandwiched between the backsheet 220 and the front-side layer 230. Subsequently, the laminate construction is heated under vacuum, causing the encapsulant sheets to become liquefied enough to flow around and encapsulate the PV cells 202a-202c, while simultaneously filling any voids in the space between the backsheet 220 and the front-side layer 230. Upon cooling, the liquefied encapsulant solidifies. In some embodiments, the encapsulant 240 may additionally be cured in situ to form a transparent solid matrix. The encapsulant 240 adheres to the backsheet 220 and the front-side layer 230 to form a laminated subassembly.

With the general construction of the PV module 200 in mind, FIG. 6A reflects that the first PV cell 202a is electrically connected to the second PV cell 202a by a first electrical connector or tabbing ribbon 204a. The first electrical connector 204a extends across the entire length of and over the first PV cell 202a, extending beyond the edge of the first PV cell 202a, and bending down and under the second PV cell 202b. The first electrical connector 204a then extends across the entire length of and underneath the second PV cell 202b. A similar relationship is established by a second electrical connector or tabbing ribbon 204b relative to the second and third PV cells 202b, 202c, as well as by additional electrical connectors relative to adjacent pairs of additional PV cells provided with the PV module 200. FIG. 6B shows a similar relationship between the light redirecting/tabbing ribbon elements 207a and 207b and the PV cells 202a, 202b, and 202c being connected by such elements. FIG. 7A is a simplified top view representation of the PV module 200 during an intermediate stage of manufacture and prior to application of the light redirecting film article(s) 210. The array of PV cells 202 generates a length direction LD and a width direction WD, with various tabbing ribbons 204 being aligned in the length direction LD (e.g., FIG. 7A identifies the first and second electrical connectors 204a, 204b described above) to collectively establish tabbing ribbon lines 250 (referenced generally). With additional reference to FIG. 7B, strips of the light redirecting film article 210 can be applied along respective tabbing ribbon lines 250, completely overlapping the corresponding electrical connectors 204 (e.g., a first strip of light redirecting film article 210a extends along a first tabbing ribbon line 250a covering the first and second tabbing ribbons 204a, 204b, and all other tabbing ribbons of the first tabbing ribbon line 250a; a second strip of light redirecting film article 210b extends along a second tabbing ribbon line 250b; etc.). With this exemplary construction, each strip of the light redirecting film article 210 optionally extends continuously across a length of the PV module 200. As mentioned before, in some embodiments, the light redirecting film article 210 can be applied to other inactive regions of the PV module 200, such as between adjacent ones of the PV cells 202, around a perimeter of one or more of the PV cells 202, etc. In related embodiments, differently formatted versions (in terms of at least bias angle B) of the light redirecting film articles of the present disclosure can be utilized in different inactive regions of the PV module 200. For example, the bias angle B of the light redirecting film article arranged so as to extend in the length direction LD (e.g., between two immediately adjacent ones of the PV cells 202) can be different from that of a light redirecting film article arranged to extend in the width direction WD (e.g., between another two immediately adjacent PV cells 202).

FIG. 7B further illustrates, in greatly exaggerated form, reflectorized microstructures 260 provided with each of the strips of the light redirecting film articles 210 commensurate with the above descriptions. In some exemplary embodiments, the reflectorized microstructures 260 are identically formed along at least one of the light redirecting film articles 210, with the primary axis A of all the reflectorized microstructures 260 being substantially parallel and oblique with respect to the corresponding longitudinal axis X of the light redirecting film article 210. By way of example, reflectorized microstructures 260 of the first light redirecting film article 210a identified in FIG. 7B are oblique to the longitudinal axis X of the first light redirecting film article 210a. The first light redirecting film article 210a is applied in the lengthwise direction LD, such that the longitudinal axis X of the first light directing film article 210a is parallel with the length direction LD of the PV module 200; thus, the primary axis A of each of the reflectorized microstructures 260 of the first light redirecting film article 210a is also oblique with respect to the length direction LD. Because the longitudinal axis X and the length direction LD are parallel, the bias angle B described above also exists relative to the length direction LD. In other words, upon final assembly, the primary axis A of one or more or all of the reflectorized microstructures 260 of the first light directing film article 210a combine or intersect with the length direction LD to establish the bias angle B as described above; the bias angle B can be on the order of 45° (plus or minus 5°) in some non-limiting embodiments. In other embodiments, for example in embodiments in which the PV module is in the portrait orientation, the bias angle B is from 65° to 90°, or from 70° to 90°, or from 75° to 90°, or from 80° to 90°, or from 80° to 85°, or 80°, or 81°, or 82°, or 83°, or 84°, or 85°, or 86°, or 87°, or 88°, or 89°, or 90°. In related embodiments, each of the strips of the light redirecting film articles 210, as applied along a respective one of the tabbing ribbon lines 250, are identically formed and are substantially identically oriented (e.g., within 10% of a truly identical relationship) relative to the length direction LD. While the light redirecting film articles 210 are illustrated in FIG. 7B as each extending continuously across the PV module 200, in other embodiments, the light redirecting film article 210 can be a smaller-length strip or segment applied to an individual one of the PV cells 202 for example. Regardless, in some configurations, the primary axis A of all of the reflectorized microstructures 260 of all of the light redirecting film articles 210 (at least as applied over the tabbing ribbon lines 250) are oblique with respect to the length direction LD in some embodiments. In related optional embodiments in which other inactive regions of the PV module are covered by a light redirecting film article of the present disclosure and arranged so as to extend in the width direction WD (or any other direction other than the length direction LD), the so-applied light redirecting film article format (in term of bias angle B) can differ from that of the light redirecting film article 210 as shown. In some embodiments, including embodiments in which the PV module is in the portrait orientation or embodiments in which the bias angle is 45° (plus or minus 5°), the light redirecting film article format can be selected as a function of the particular installation site, for example such that upon final installation, the primary axis of the corresponding reflectorized microstructures are all substantially aligned with the East-West direction of the installation site (e.g., the primary axis deviates no more than 45 degrees from the East-West direction, optionally no more than 20 degrees from the East-West direction, alternatively no more than 5 degrees from the East-West direction, alternatively aligned with, the East-West direction).

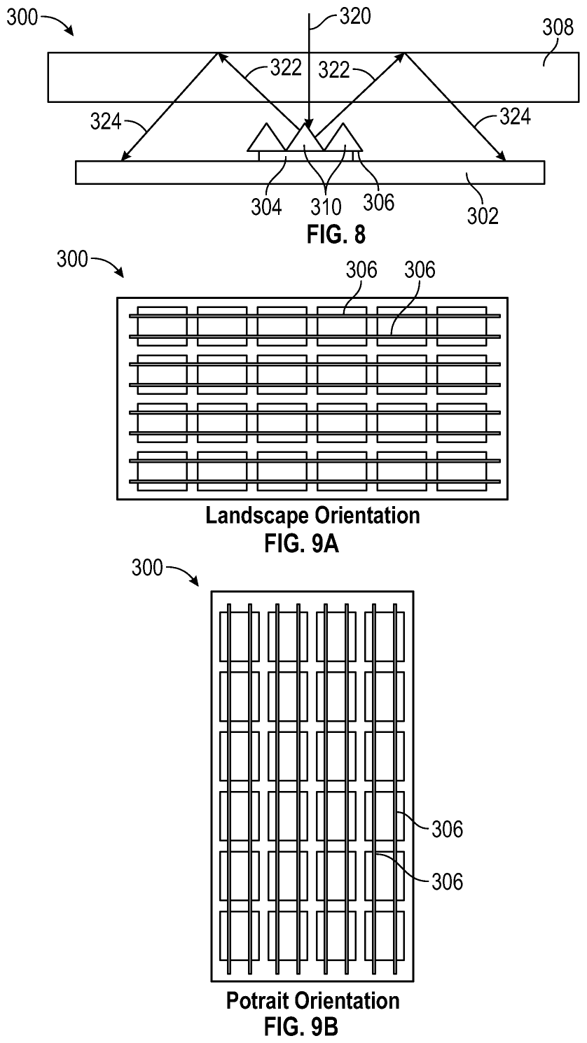

It has surprisingly been found that PV modules incorporating the light redirecting film articles in accordance with the present disclosure have increased optical efficiency as compared to conventional designs. As a point of reference, FIG. 8 is a simplified representation of a portion of a conventional PV module 300, including a PV cell 302 and an electrical connector 304. A conventional light reflecting film 306 is disposed over the electrical connector 304. A front-side layer 308 (e.g., glass) covers the assembly. The light reflecting film 306 includes reflective microprisms 310 (a size of each of which is greatly exaggerated in FIG. 8). Incident light (identified by arrow 320) impinging on the light reflecting film 306 is discretely reflected (identified by arrows 322) is discretely reflected back at angles of larger than the critical angle of the front-side layer 308. This light undergoes total internal reflection (TIR) to reflect back (identified by arrows 324) back to the PV cell 302 (or other PV cells of the PV module 300) for absorption. Typically, the normal incidence beam 320 can undergo a total deviation of more than 26° in the plane perpendicular to the primary axis of the reflective microprisms 310 before TIR is defeated.

The reflective microprisms 310 are illustrated in FIG. 8 as being in-line or parallel with the longitudinal axis of the conventional light reflecting film 306 (i.e., the light reflecting film 306 is different from the light redirecting films and articles of the present disclosure, and the corresponding PV module 300 is different from the PV modules of the present disclosure). Under circumstances where the PV module 300 is part of a two-dimensional tracking-type PV module installation, the PV module 300 will track movement of the sun, such that over the course of the day, incident light will have the approximate relationship relative to the reflective microprisms 310 as shown, desirably experiencing reflection at angles larger than the critical angle. Under circumstances where the PV module 300 is part of a one-dimensional tracking-type PV module installation, the PV module 300 will track movement of the sun, but incident light is not guaranteed to have the approximate relationship relative to the reflective microprisms 310 as shown over the course of the day, and may not generate reflection angles that correspond to TIR at all times. Further, where the particular installation is stationary or non-tracking, as the angle of sun changes with respect to the facet angle(s) of the reflective microprisms 310, some of the light will be reflected at angles outside of the critical angle and escape back through the front-side layer 308. Non-tracking systems inherently have some degree of asymmetry as the sun's position relative to the PV module changes throughout the day and year. The angle of incidence of the sun with respect to the face of the PV module will change by up to 180° (East to West) over the course of the day, and by up to 47° (North to South) over the year.

In FIG. 8, due to changes in the sun's position over the course of the day and year (relative to a non-tracking or stationary PV module installation), the angular response of the reflective microprisms 310 is not uniform at all angles of incidence. This angular response coupled with the solar path effectively dictates that the conventional PV module 300, and in particular the conventional light reflecting film 306 as incorporated therein, is orientation dependent. More particularly, with conventional constructions in which the reflective microprisms 310 are parallel or aligned with the length direction LD (not identified in FIG. 8, but will be understood to be into a plane of the page of FIG. 8) of the PV module 300, the light reflecting film 306 will increase the energy output for the PV module 300 to a certain extent, though at a less-than optimal level as the sun's position changes over the course of the day and year. A spatial orientation of the length direction LD relative to the sun will also impact the optical efficiency of the PV module 300/light reflecting film 306. Typically, and as shown by a comparison of FIGS. 9A and 9B, non-tracking PV modules are installed in either a landscape orientation (FIG. 9A) or a portrait orientation (FIG. 9B). In the landscape orientation, the reflective prisms 310 (FIG. 8) are aligned with the East-West direction; in the portrait orientation, the reflective prisms 310 are aligned with North-South direction. Thus, when the bias angle is zero, the angular response of the reflective prisms 310 coupled with the solar path results in the landscape orientation of the PV module 300 having an increased energy output as compared to the same PV module 300 in the portrait orientation as described below.

The discussion that follows in this paragraph assumes that the bias angle for the light redirecting film article is zero when installed on the PV modules either in landscape or portrait. In the landscape orientation (FIG. 9A), light reflecting from the reflective prisms 310 (FIG. 8) is directed almost exclusively within angles trapped by TIR at the interface of external air and the front-side layer 308 (FIG. 8). In portrait orientation (FIG. 9B), light reflecting from the reflective prisms 310 is directed into angles trapped by TIR only between certain hours of day light (e.g., mid-day such as between 10:00 AM and 2:00 PM). During the remainder of the day, light is only partially reflected at the interface of external air and the front-side layer 308 onto the PV module. The present disclosure overcomes the orientation dependent drawbacks of previous PV modules designs. In particular, by incorporating the light redirecting film articles of the present disclosure into the PV module construction, optical efficiency of the resultant PV module is similarly increased regardless of portrait or landscape orientation. For example, and returning to the non-limiting embodiment of FIG. 7B, the light redirecting film articles 210 otherwise covering the tabbing ribbons 204 (FIG. 7A), can be constructed and arranged relative to the length direction LD of the PV module 200 such that the primary axis A of each of the reflectorized microstructures 260 is biased 45° relative to the longitudinal axis X (i.e., the bias angle B as described above is 45°) and thus relative to the length direction LD.

Another embodiment of a light redirecting film of the present disclosure performs most efficiently in a portrait orientated module. The landscape orientated module having such light redirecting film is then disadvantaged. In particular, by incorporating the light redirecting film articles of the present disclosure into the PV module construction, the orientation dependence of the optical efficiency of the resultant PV module is transposed. For example, and returning to the non-limiting embodiment of FIG. 7B for illustration purposes, the light redirecting film articles 210 otherwise covering the tabbing ribbons 204 (FIG. 7A), can be constructed and arranged relative to the length direction LD of the PV module 200 such that the primary axis A of each of the reflectorized microstructures 260 is biased 82° relative to the longitudinal axis X (i.e., the bias angle B as described above is 82°) and thus relative to the length direction LD. A light redirecting film with a bias angle of −82° yields similar results as a light redirecting film with a bias angle of 82°. More generally, the annualized energy results for a light redirecting film with a bias angle of −B degrees yields similar results as a light redirecting film with a bias angle of +B degrees.

Table 1 shows the results of various bias angle reflective microprisms from ray trace modeling for a 10° module tilt at 30° North latitude (similar in latitude to a module located in Shanghai, China or Austin, Tex.). The solar angles were calculated in 10 minute intervals over the course of one year for use as input to the ray tracing algorithm. The amount of light absorbed by the PV cell was calculated for each solar angle. The total light absorbed was obtained by weighting each solar angle result by the solar irradiance as calculated by Hottel's clear sky model. Table 1 contains the percent improvement for PV modules with light redirecting film articles as compared to PV modules without light redirecting film articles.

TABLE 1
Tabular results of bias angle versus percent annual
improvement for 30° latitude and 10° tilt
for PV modules in landscape and portrait orientation.

| Bias Angle | Landscape Oriented | Portrait Oriented |
|---|---|---|
| 0 | 1.76% | 1.25% |
| 5 | 1.76% | 1.25% |
| 10 | 1.75% | 1.27% |
| 15 | 1.75% | 1.29% |
| 20 | 1.74% | 1.31% |
| 25 | 1.73% | 1.34% |
| 30 | 1.70% | 1.39% |
| 35 | 1.66% | 1.47% |
| 40 | 1.61% | 1.50% |
| 45 | 1.56% | 1.51% |
| 50 | 1.49% | 1.52% |
| 55 | 1.38% | 1.53% |
| 60 | 1.27% | 1.54% |
| 65 | 1.23% | 1.58% |
| 70 | 1.22% | 1.60% |
| 75 | 1.19% | 1.61% |
| 80 | 1.16% | 1.62% |
| 82 | 1.13% | 1.62% |
| 85 | 1.04% | 1.62% |
| 90 | 0.92% | 1.62% |

One embodiment of a successful light redirecting film article of the present disclosure is the non-limiting example of a light redirecting film article (i.e., with a bias angle B of 82°) of the present disclosure in combination with a PV module. In other embodiment PV modules in accordance with principles of the present disclosure, the obliquely arranged reflectorized microstructures of the provided light redirecting film article(s) (e.g., covering at least portions of one or more of the tabbing ribbons) can have a bias angle other than 82° and improved efficiencies achieved. In addition or alternatively, the facet(s) of the microstructures (and thus of the resultant reflectorized microstructures) can exhibit non-uniformities that modify the reflected irradiance. For example, and as described above, in some embodiments the light redirecting film useful with the light redirecting film articles of the present disclosure can be manufactured using a microreplication tool that is generated by a fly-wheel (or similar) cutting process that inherently imparts variations into the tool, and thus into the reflectorized microstructure facet(s). When employed as part of a PV module (e.g., covering at least a portion of a tabbing ribbon), light impinging on the facet variations experiences diffusion that in turns spreads the reflected beam of what would otherwise be a specular reflection (i.e., were the variations not present). As a point of reference, if the specularly reflected beam would be at an angle outside of the critical angle for TIR, it may escape the PV module into a narrow angular range and may cause stray light or glare. It is expected that even modest diffusion of the reflected light by plus or minus 1° spreads the reflection in such a way as to decrease the radiance of this stray light by a factor of 25.

Returning to FIG. 7B for illustration purposes, the light redirecting film articles 210 can be formatted to provide a common bias angle B that is “tuned” to the particular installation conditions of the PV module 200, optionally balancing orientation and seasonality. For example, in some embodiments of the present disclosure, the PV module manufacturer can have different versions of the light redirecting film articles of the present disclosure available, each version providing a different reflectorized microstructure bias angle. The PV module manufacturer then evaluates the conditions of a particular installation site and selects the light redirecting film article having a reflectorized microstructure bias angle best suited for those conditions. In related embodiments, a manufacturer of the light redirecting film articles of the present disclosure can be informed by the PV module manufacturer of the conditions of a particular installation and then generate a light redirecting film article having a bias angle best suited for those conditions.

In addition to optionally rendering the PV module 200 to be orientation independent (in terms of optical efficiency of the light redirecting film articles 210 having a bias angle of 45° as applied over the tabbing ribbons 204 (FIG. 7A)) or providing maximum efficiency with light redirecting film articles 210 having a bias angle of, for example, 82°, the light redirecting film articles and corresponding PV modules of the present disclosure can offer other advantages over PV modules conventionally incorporating a light reflecting film with reflective microprisms arranged in the on-axis direction. For example, with a conventional PV module having on-axis reflective microprisms and arranged in the portrait orientation (e.g., the PV module 300 of FIG. 9B), glare is oftentimes evident during the times light reflected by the light reflecting film 306 does not undergo TIR at the interface between external air and the front-side layer 208 (FIG. 8). The angle of the reflected light causing glare changes as the sun moves. With the light redirecting film articles and corresponding PV modules of the present disclosure, the time of day and seasonality of the glare, if any, can be shifted as desired (as a function of the bias angle selected for the light redirecting film articles incorporated into the PV module). For example, the light redirecting film article, as applied over the tabbing ribbons, can be formatted such that glare into a building proximate the PV module installation during the afternoon is avoided.

Additionally, it is sometimes the case that installation site restrictions do not allow the PV module to face due south (in Northern Hemisphere locations) as would otherwise be desired. The performance of a non-South facing (Northern Hemisphere), conventional PV modules (otherwise incorporating a light reflecting film with on-axis reflective microprisms) is undesirably skewed. The light redirecting film articles and corresponding PV modules of the present disclosure can be formatted to overcome these concerns, incorporating a biased reflectorized microstructure orientation that corrects for the expected skew.

While some of the present disclosure has exemplified the use of light redirecting film articles on tabbing ribbons, as mentioned before, the light redirecting film articles having non-zero biased angles of the present disclosure can also be used on areas of the PV module that have no PV cells, such as, for example, in between PV cells and around the perimeter of the cells.

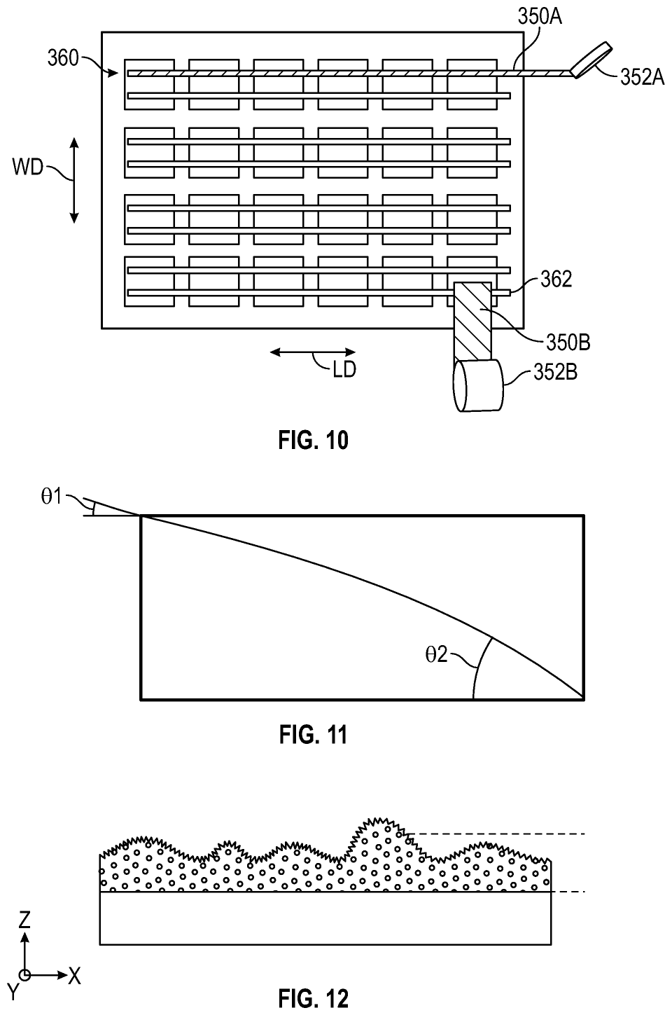

Further optional benefits associated with some embodiments of the present disclosure relate to flexibility in the manufacture of a PV module. With reference to FIG. 10, PV manufactures may sometimes desire to apply strips of the light redirecting film article in the length direction LD (e.g., applied over one of the tabbing ribbons in the same direction as the tabbing ribbon). This approach is reflected in FIG. 10 by a strip of a light redirecting film article 350A being applied, from a first roll 352A, in the length direction LD along a first tabbing ribbon line 360. In other instances, it is desired to apply the light redirecting film article in the width direction WD (e.g., perpendicular to a length of one of the tabbing ribbons and cut to a width of the tabbing ribbon in situ). For example, FIG. 10 shows a strip of a light redirecting film article 350B being applied, from a second roll 352B, to a second tabbing ribbon 362. With non-limiting embodiments which the PV module manufacturer is provided with a light redirecting film article in accordance with principles of the present disclosure and having a reflectorized microstructure bias angle B of 45°, the PV module manufacturer is afforded the flexibility of applying the light redirecting film article in either direction yet still achieve the benefits described above. For example, the same roll 352A or 352B can be used to apply the corresponding light redirecting film article 350A or 350B in either the length direction LD or the width direction WD. Any bias angle may be manufactured to allow application from a roll 350A or 350B. The condition on the bias angle is such that the bias angle of roll 350A and the bias angle of roll 350B are complementary.

The light redirecting film articles of the present disclosure provide a marked improvement over previous designs. The biased angle, reflective surface microstructures of the light redirecting film articles present unique optical properties not available with conventional on-axis light redirecting films. The light redirecting film articles of the present disclosure have numerous end use applications, such as, for example, with PV modules. The PV modules of the present disclosure can have improved efficiencies independent of orientation. Moreover, other improvements to PV module performance can be achieved with the light redirecting film articles of the present disclosure.

Although the present disclosure has been described with reference to preferred embodiments, workers skilled in the art will recognize that changes can be made in form and detail without departing from the spirit and scope of the present disclosure. For example, while the light redirecting film articles of the present disclosure have been described as being useful with PV modules, multiple other end-use applications are equally acceptable. The present disclosure is in no way limited to PV modules.

### Exemplary Embodiments

The following embodiments are exemplary and non-limiting, and represent examples of LRF articles that comprise light redirecting films that can be modified in any of the ways described above to yield LRF films or articles that reduce the generation of stray light.

Embodiment 1. A light redirecting film article comprising:
a light redirecting film defining a longitudinal axis and including:
   a base layer;
   an ordered arrangement of a plurality of microstructures projecting from the base layer;
   wherein each of the microstructures extends along the base layer to define a corresponding primary axis;
   and further wherein the primary axis of at least one of the microstructures is oblique with respect to the longitudinal axis; and
a reflective layer over the microstructures opposite the base layer.

Embodiment 2. The light redirecting film article of embodiment 1, wherein the primary axis of a majority of the microstructures is oblique with respect to the longitudinal axis.

Embodiment 3. The light redirecting film article of any of the preceding embodiments, wherein the primary axis of all of the microstructures is oblique with respect to the longitudinal axis.

Embodiment 4a. The light redirecting film article of any of the preceding embodiments, wherein the longitudinal axis and the primary axis of the at least one microstructure form a bias angle in the range of 1°-90°.

Embodiment 4b. The light redirecting film article of any of the preceding embodiments, wherein the longitudinal axis and the primary axis of all of the microstructures form a bias angle in the range of 1°-90°.

Embodiment 4c. The light redirecting film article of any of the preceding embodiments, wherein the longitudinal axis and the primary axis of the at least one microstructure form a bias angle in the range of −1°-−90°.

Embodiment 4d. The light redirecting film article of any of the preceding embodiments, wherein the longitudinal axis and the primary axis of all of the microstructures form a bias angle in the range of −1°-−90°.

Embodiment 5a. The light redirecting film article of any of the preceding embodiments, wherein the longitudinal axis and the primary axis of the at least one microstructure form a bias angle in the range of 1°-89°.

Embodiment 5b. The light redirecting film article of any of the preceding embodiments, wherein the longitudinal axis and the primary axis of all of the microstructures form a bias angle in the range of 1°-89°.

Embodiment 5c. The light redirecting film article of any of the preceding embodiments, wherein the longitudinal axis and the primary axis of the at least one microstructure form a bias angle in the range of −1°-−89°.

Embodiment 5d. The light redirecting film article of any of the preceding embodiments, wherein the longitudinal axis and the primary axis of all of the microstructures form a bias angle in the range of −1°-−89°.

Embodiment 6a. The light redirecting film article of any of the preceding embodiments, wherein the longitudinal axis and the primary axis of the at least one microstructure form a bias angle is in the range of 20°-70°.

Embodiment 6b. The light redirecting film article of any of the preceding embodiments, wherein primary axis of each of the microstructures and the longitudinal axis form a bias angle in the range of 20°-70°.

Embodiment 7a. The light redirecting film article of any of the preceding embodiments, wherein the longitudinal axis and the primary axis of the at least one microstructure form a bias angle is in the range of −20°-7-0°.

Embodiment 7b. The light redirecting film article of any of the preceding embodiments, wherein primary axis of each of the microstructures and the longitudinal axis form a bias angle in the range of −20°-−70°.

Embodiment 8a. The light redirecting film article of any of the preceding embodiments, wherein the longitudinal axis and the primary axis of the at least one microstructure form a bias angle is about 45°.

Embodiment 8b. The light redirecting film article of any of the preceding embodiments, wherein the longitudinal axis and the primary axis of all of the microstructures form a bias angle is about 45°.

Embodiment 8c. The light redirecting film article of any of the preceding embodiments, wherein the longitudinal axis and the primary axis of the at least one microstructure form a bias angle is about −45°.

Embodiment 8d. The light redirecting film article of any of the preceding embodiments, wherein the longitudinal axis and the primary axis of all of the microstructures form a bias angle is about −45°.

Embodiment 9. The light redirecting film article of any of the preceding embodiments, wherein the light directing film is a strip having opposing end edges and opposing side edges, a length of the strip being defined between the opposing end edges and a width of the strip being defined between the opposing side edges, and further wherein the length is at least 10× the width, and even further wherein the longitudinal axis is in a direction of the length.

Embodiment 10. The light redirecting film article of any of the preceding embodiments, wherein each of the microstructures has a substantially triangular prism shape.

Embodiment 11. The light redirecting film article of any of the preceding embodiments, wherein each of the microstructures has a substantially triangular prism shape and wherein the primary axis is defined along a peak of the substantially triangular prism shape.

Embodiment 12. The light redirecting film article of any of the preceding embodiments, wherein each of the microstructures has a substantially triangular prism shape, wherein the primary axis is defined along a peak of the substantially triangular prism shape, wherein the substantially triangular prism shape includes opposing facets extending from the corresponding peak to the base layer, and further wherein at least one of the peak and opposing sides of at least one of the microstructures is non-linear in extension along the base layer.

Embodiment 13. The light redirecting film article of any of the preceding embodiments, wherein each of the microstructures has a substantially triangular prism shape, wherein the primary axis is defined along a peak of the substantially triangular prism shape, and wherein the peak of at least some of the microstructures is rounded.

Embodiment 14. The light redirecting film article of any of the preceding embodiments, wherein a peak of the substantially triangular prism shape defines an apex angle of about 120°.

Embodiment 15. The light redirecting film article of any of the preceding embodiments, wherein the microstructures project 5 micrometers-500 micrometers from the base layer.

Embodiment 16. The light redirecting film article of any of the preceding embodiments, wherein the base layer comprises a polymeric material.

Embodiment 17. The light redirecting film article of any of the preceding embodiments, wherein the microstructures comprise a polymeric material.

Embodiment 18. The light redirecting film article of any of the preceding embodiments, wherein the microstructures comprise a polymeric material, and wherein the microstructures comprises the same polymeric material as the base layer.

Embodiment 19. The light redirecting film article of any of the preceding embodiments, wherein the reflective layer comprises a material coating selected from the group consisting of a metallic material, an inorganic material, and an organic material.

Embodiment 20. The light redirecting film article of any of the preceding embodiments, further comprising an adhesive carried by the base layer opposite the microstructures.

Embodiment 21. The light redirecting film article of any of the preceding embodiments, wherein the light redirecting film is formed as a roll having a roll width of not more than 15.25 cm (6 inches).

Embodiment 22. A PV module, comprising:
a plurality of PV cells electrically connected by tabbing ribbons; and
a light redirecting film article applied over at least a portion of at least one of the tabbing ribbons, the light redirecting film article comprising:
a light redirecting film defining a longitudinal axis and including:
   a base layer,
   an ordered arrangement of a plurality of microstructures projecting from the base layer,
   wherein each of the microstructures extends along the base layer to define a corresponding primary axis,
   and further wherein the primary axis of at least one of the microstructures is oblique with respect to the longitudinal axis, and
a reflective layer over the microstructures opposite the base layer.

Embodiment 23. The PV module of any of the preceding embodiments directed to PV modules, wherein the at least one tabbing ribbon defines a length direction, and further wherein the light redirecting film article as applied over the at least one tabbing ribbon arranges the primary axis of the at least one microstructure to be oblique with respect to the length direction.

Embodiment 24. The PV module of any of the preceding embodiments directed to PV modules, further comprising the light redirecting film article applied to at least one additional region that is free of the PV cells.

Embodiment 25. The PV module of any of the preceding embodiments directed to PV modules, further comprising the light redirecting film article applied to at least one additional region that is free of the PV cells, and wherein the at least one additional region is a perimeter of at least one of the PV cells.

Embodiment 26. The PV module of any of the preceding embodiments directed to PV modules, further comprising the light redirecting film article applied to at least one additional region that is free of the PV cells, and wherein the at least one additional region is an area between an immediately adjacent pair of the PV cells.

Embodiment 27. The PV module of any of the preceding embodiments directed to PV modules, wherein the PV module exhibits substantially similar annual efficiency performance when installed in a landscape orientation or a portrait orientation.

Embodiment 28. A method of making a PV module including a plurality of PV cells electrically connected by tabbing ribbons, the method comprising:
applying a light redirecting film article over at least a portion of at least one of the tabbing ribbons, the light redirecting film article comprising:
a light redirecting film defining a longitudinal axis and including:
   a base layer,
   an ordered arrangement of a plurality of microstructures projecting from the base layer,
   wherein each of the microstructures extends along the base layer to define a corresponding primary axis,
   and further wherein the primary axis of at least one of the microstructures is oblique with respect to the longitudinal axis, and
a reflective layer over the microstructures opposite the base layer.

Embodiment 29. The method of any of the preceding embodiments directed to methods of making a PV module, further comprising applying a length of the light redirecting film article to a region between immediately adjacent ones of the PV cells.

Embodiment 30. The method of any of the preceding embodiments directed to methods of making a PV module, further comprising applying a length of the light redirecting film article about a perimeter of at least one of the PV cells.

Embodiment 31. A method of installing a PV module at an installation site, the PV module including a plurality of spaced apart PV cells arranged to define regions of the PV module that are free of PV cells, the method comprising:
applying a first light redirecting film article over at least a portion of one of the regions free of PV cells, the first light redirecting film article including:
a light redirecting film defining a longitudinal axis and including:
   a base layer,
   an ordered arrangement of a plurality of microstructures projecting from the base layer,
   wherein each of the microstructures extends along the base layer to define a corresponding primary axis,
   and further wherein the primary axis of at least one of the microstructures is oblique with respect to the longitudinal axis, and
a reflective layer over the microstructures opposite the base layer; and
mounting the PV module at the installation site;

wherein following the step of mounting, the primary axis of the at least one microstructure is substantially aligned with an East-West direction of the installation site.

Embodiment 32. The method of any of the preceding embodiments directed to methods of installing a PV module at an installation site, wherein following the step of applying the light redirecting film, a front-side layer is disposed over the PV cells in completing the PV module.

Embodiment 33. The method of any of the preceding embodiments directed to methods of installing a PV module at an installation site, wherein following the step of mounting, the primary axis of the at least one microstructure defines an angle with respect to the East-West direction of no more than 45 degrees.

Embodiment 34. The method of any of the preceding embodiments directed to methods of installing a PV module at an installation site, wherein following the step of mounting, the primary axis of the at least one microstructure defines an angle with respect to the East-West direction of no more than 20 degrees.

Embodiment 35. The method of any of the preceding embodiments directed to methods of installing a PV module at an installation site, wherein following the step of mounting, the primary axis of the at least one microstructure defines an angle with respect to the East-West direction of no more than 5 degrees.

Embodiment 36. The method of any of the preceding embodiments directed to methods of installing a PV module at an installation site, wherein the PV module defines a length direction and a width direction, and further wherein the light redirecting film article is disposed between two immediately adjacent ones of the PV cells and extends in the length direction.

Embodiment 37. The method of any of the preceding embodiments directed to methods of installing a PV module at an installation site, wherein the PV module defines a length direction and a width direction, and further wherein the light redirecting film article is disposed between two immediately adjacent ones of the PV cells and extends in the width direction.

Embodiment 38. The method of any of the preceding embodiments directed to methods of installing a PV module at an installation site, further comprising: applying a second light redirecting film article over at least a portion of a second one of the regions free of the PV cells, the second light redirecting film article including:
a light redirecting film defining a longitudinal axis and including:
   a base layer,
   an ordered arrangement of a plurality of microstructures projecting from the base layer,
   wherein each of the microstructures extends along the base layer to define a corresponding primary axis,
   and further wherein the primary axis of at least one of the microstructures is oblique with respect to the longitudinal axis, and
a reflective layer over the microstructures opposite the base layer;

wherein the first and second light redirecting film articles extend in differing directions relative to a perimeter shape of the PV module;

and further wherein following the step of mounting, the primary axis of the at least one microstructure of the second light redirecting film article is substantially aligned with the East-West direction of the installation site.

Embodiment 39. The method of embodiment 38, wherein a bias angle of the at least one microstructure of the first light redirecting film article differs from a bias angle of the at least one microstructure of the second light redirecting film article.

Embodiment 40. A PV module, comprising:

a plurality of PV cells electrically connected by tabbing ribbons; and

a light redirecting film article applied over article applied to at least one region that is free of the PV cells, the light redirecting film article comprising:
a light redirecting film defining a longitudinal axis and including:
   a base layer,
   an ordered arrangement of a plurality of microstructures projecting from the base layer,
   wherein each of the microstructures extends along the base layer to define a corresponding primary axis,
   and further wherein the primary axis of at least one of the microstructures is oblique with respect to the longitudinal axis, and
a reflective layer over the microstructures opposite the base layer.

Embodiment 41. The PV module of embodiment 40, wherein the at least one tabbing ribbon defines a length direction, and further wherein the light redirecting film article applied over the at least one region that is free of the PV cells arranges the primary axis of the at least one microstructure to be oblique with respect to the length direction.

Embodiment 42. The PV module of any one of embodiments 40 to 41, wherein the at least one region that is free of the PV cells is a perimeter of at least one of the PV cells.

Embodiment 43. The PV module of any one of embodiments 40 to 42, wherein the at least one region that is free of the PV cells is an area between an immediately adjacent pair of the PV cells.

Embodiment 44. The PV module of any one of embodiments 40 to 43, wherein the PV module exhibits substantially similar annual efficiency performance when installed in a landscape orientation or a portrait orientation.

Embodiment 45a. The PV module of any one of embodiments 40 to 44, wherein the longitudinal axis and the primary axis of the at least one microstructure form a bias angle in the range of 1°-90°.

Embodiment 45b. The PV module of any one of embodiments 40 to 44, wherein the longitudinal axis and the primary axis of all of the microstructures form a bias angle in the range of 1°-90°.

Embodiment 45c. The PV module of any one of embodiments 40 to 44, wherein the longitudinal axis and the primary axis of the at least one microstructure form a bias angle in the range of −1°-−90°.

Embodiment 45d. The PV module of any one of embodiments 40 to 44, wherein the longitudinal axis and the primary axis of all of the microstructures form a bias angle in the range of −1°-−90°.

Embodiment 46a. The PV module of any one of embodiments 40 to 45, wherein the longitudinal axis and the primary axis of the at least one microstructure form a bias angle in the range of 1°-89°.

Embodiment 46b. The PV module of any one of embodiments 40 to 45, wherein the longitudinal axis and the primary axis of all of the microstructures form a bias angle in the range of 1°-89°.

Embodiment 46c. The PV module of any one of embodiments 40 to 45, wherein the longitudinal axis and the primary axis of the at least one microstructure form a bias angle in the range of −1°-−89°.

Embodiment 46d. The PV module of any one of embodiments 40 to 45, wherein the longitudinal axis and the primary axis of all of the microstructures form a bias angle in the range of −1°-−89°.

Embodiment 47a. The PV module of any one of embodiments 40 to 46, wherein the longitudinal axis and the primary axis of the at least one microstructure form a bias angle is in the range of 20°-70°.

Embodiment 47b. The PV module of any one of embodiments 40 to 47, wherein primary axis of each of the microstructures and the longitudinal axis form a bias angle in the range of 20°-70°.

Embodiment 48a. The PV module of any one of embodiments 40 to 46, wherein the longitudinal axis and the primary axis of the at least one microstructure form a bias angle is in the range of −20°-−70°.

Embodiment 48b. The PV module of any one of embodiments 40 to 47, wherein primary axis of each of the microstructures and the longitudinal axis form a bias angle in the range of −20°-−70°.

Embodiment 49. The PV module of any one of embodiments 40 to 48, wherein the longitudinal axis and the primary axis of the at least one microstructure form a bias angle is about 45°.

Embodiment 49a. The PV module of any one of embodiments 40 to 48, wherein the longitudinal axis and the primary axis of all of the microstructures form a bias angle is about −45°.

Embodiment 50a. The PV module of any one of embodiments 40 to 48, wherein the longitudinal axis and the primary axis of the at least one microstructure form a bias angle is about 45°.

Embodiment 50b. The PV module of any one of embodiments 40 to 48, wherein the longitudinal axis and the primary axis of all of the microstructures form a bias angle is about −45°.

### Further Exemplary Embodiments

The following embodiments are additional exemplary embodiments of LRF or LRF articles that can be modified in any of the ways described above to yield LRF or LRF articles that reduce the generation of stray light.
1. A light redirecting film article comprising:

a light redirecting film defining a longitudinal axis and including:
a base layer;
an ordered arrangement of a plurality of microstructures projecting from the base layer;
wherein each of the microstructures extends along the base layer to define a corresponding primary axis;
wherein the primary axis of at least one of the microstructures is oblique with respect to the longitudinal axis;
and further wherein the longitudinal axis and the primary axis of the at least one microstructure define a bias angle, and

a reflective layer over the microstructures opposite the base layer.
2. The light redirecting film article of embodiment 1, wherein the primary axis of a majority of the microstructures is oblique with respect to the longitudinal axis.
3. The light redirecting film article according to any of the preceding embodiments, wherein the primary axis of all of the microstructures is oblique with respect to the longitudinal axis.
4. The light redirecting film article according to any of the preceding embodiments, wherein the bias angle is in the range of 1° to 90°.
5. The light redirecting film article according to any of the preceding embodiments, wherein the bias angle is in the range of 1° to 89°.
6. The light redirecting film article according to any of the preceding embodiments, wherein the bias angle is in the range of 20° to 70°.
7. The light redirecting film article according to any of the preceding embodiments, wherein the bias angle formed between the primary axis and the longitudinal axis of each of the microstructures is in the range of −1° to −90°.
8. The light redirecting film article according to any of the preceding embodiments, wherein the bias angle formed between the primary axis and the longitudinal axis of each of the microstructures is in the range of −1° to −89°.
9. The light redirecting film article according to any of the preceding embodiments, wherein the bias angle formed between the primary axis and the longitudinal axis of each of the microstructures is in the range of −20° to −70°.
10. The light redirecting film article according to any of the preceding embodiments, wherein the bias angle is 45° plus or minus 2 degrees.
11. The light redirecting film article according to any of the preceding embodiments, wherein the bias angle is from 65° to 90°.
12. The light redirecting film article according to any of the preceding embodiments, wherein the bias angle is from 70° to 90°.
13. The light redirecting film article according to any of the preceding embodiments, wherein the bias angle is from 75° to 90°.
14. The light redirecting film article according to any of the preceding embodiments, wherein the bias angle is from 75° to 85°.
15. The light redirecting film article according to any of the preceding embodiments, wherein the bias angle is from 80° to 90°.
16. The light redirecting film article according to any of the preceding embodiments, wherein the bias angle is from 80° to 85°.
17. The light redirecting film article according to any of the preceding embodiments, wherein the bias angle is −45° plus or minus 2 degrees.
18. The light redirecting film article according to any of the preceding embodiments, wherein the bias angle is from −65° to −90°.
19. The light redirecting film article according to any of the preceding embodiments, wherein the bias angle is from −70° to −90°.
20. The light redirecting film article according to any of the preceding embodiments, wherein the bias angle is from −75° to −90°.
21. The light redirecting film article according to any of the preceding embodiments, wherein the bias angle is from −75° to −85°.
22. The light redirecting film article according to any of the preceding embodiments, wherein the bias angle is from −80° to −90°.
23. The light redirecting film article according to any of the preceding embodiments, wherein the bias angle is from −80° to −85°.
24. The light redirecting film article according to any of the preceding embodiments, wherein the bias angle is 74° plus or minus 2 degrees.
25. The light redirecting film article according to any of the preceding embodiments, wherein the bias angle is 75° plus or minus 2 degrees.
26. The light redirecting film article according to any of the preceding embodiments, wherein the bias angle is 76° plus or minus 2 degrees.
27. The light redirecting film article according to any of the preceding embodiments, wherein the bias angle is 77° plus or minus 2 degrees.
28. The light redirecting film article according to any of the preceding embodiments, wherein the bias angle is 78° plus or minus 2 degrees.
29. The light redirecting film article according to any of the preceding embodiments, wherein the bias angle is 79° plus or minus 2 degrees.
30. The light redirecting film article according to any of the preceding embodiments, wherein the bias angle is 80° plus or minus 2 degrees.
31. The light redirecting film article according to any of the preceding embodiments, wherein the bias angle is 81° plus or minus 2 degrees.
32. The light redirecting film article according to any of the preceding embodiments, wherein the bias angle is 82° plus or minus 2 degrees.
33. The light redirecting film article according to any of the preceding embodiments, wherein the bias angle is 83° plus or minus 2 degrees.
34. The light redirecting film article according to any of the preceding embodiments, wherein the bias angle is 84° plus or minus 2 degrees.
35. The light redirecting film article according to any of the preceding embodiments, wherein the bias angle is 85° plus or minus 2 degrees.
36. The light redirecting film article according to any of the preceding embodiments, wherein the bias angle is 86° plus or minus 2 degrees.
37. The light redirecting film article according to any of the preceding embodiments, wherein the bias angle is 87° plus or minus 2 degrees.
38. The light redirecting film article according to any of the preceding embodiments, wherein the bias angle is 88° plus or minus 2 degrees.
39. The light redirecting film article according to any of the preceding embodiments, wherein the bias angle is 89° plus or minus 2 degrees.
40. The light redirecting film article according to any of the preceding embodiments, wherein the bias angle is 90° plus or minus 2 degrees.
41. The light redirecting film article according to any of the preceding embodiments, wherein the bias angle is −74° plus or minus 2 degrees.
42. The light redirecting film article according to any of the preceding embodiments, wherein the bias angle is −75° plus or minus 2 degrees.
43. The light redirecting film article according to any of the preceding embodiments, wherein the bias angle is −76° plus or minus 2 degrees.
44. The light redirecting film article according to any of the preceding embodiments, wherein the bias angle is −77° plus or minus 2 degrees.
45. The light redirecting film article according to any of the preceding embodiments, wherein the bias angle is −78° plus or minus 2 degrees.
46. The light redirecting film article according to any of the preceding embodiments, wherein the bias angle is −79° plus or minus 2 degrees.
47. The light redirecting film article according to any of the preceding embodiments, wherein the bias angle is −80° plus or minus 2 degrees.
48. The light redirecting film article according to any of the preceding embodiments, wherein the bias angle is −81° plus or minus 2 degrees.
49. The light redirecting film article according to any of the preceding embodiments, wherein the bias angle is −82° plus or minus 2 degrees.
50. The light redirecting film article according to any of the preceding embodiments, wherein the bias angle is −83° plus or minus 2 degrees.
51. The light redirecting film article according to any of the preceding embodiments, wherein the bias angle is −84° plus or minus 2 degrees.
52. The light redirecting film article according to any of the preceding embodiments, wherein the bias angle is −85° plus or minus 2 degrees.
53. The light redirecting film article according to any of the preceding embodiments, wherein the bias angle is −86° plus or minus 2 degrees.
54. The light redirecting film article according to any of the preceding embodiments, wherein the bias angle is −87° plus or minus 2 degrees.
55. The light redirecting film article according to any of the preceding embodiments, wherein the bias angle is −88° plus or minus 2 degrees.
56. The light redirecting film article according to any of the preceding embodiments, wherein the bias angle is −89° plus or minus 2 degrees.
57. The light redirecting film article according to any of the preceding embodiments, wherein the bias angle is −90° plus or minus 2 degrees.
58. The light redirecting film article according to any of the preceding embodiments, wherein the light directing film is a strip having opposing end edges and opposing side edges, a length of the strip being defined between the opposing end edges and a width of the strip being defined between the opposing side edges, and further wherein the length is at least 10× the width, and even further wherein the longitudinal axis is in a direction of the length.
59. The light redirecting film article according to any of the preceding embodiments, wherein each of the microstructures has a substantially triangular prism shape.
60. The light redirecting film article according to any of the preceding embodiments, wherein each of the microstructures has a substantially triangular prism shape, and wherein the primary axis is defined along a peak of the substantially triangular prism shape.
61. The light redirecting film article according to any of the preceding embodiments, wherein each of the microstructures has a substantially triangular prism shape, wherein the primary axis is defined along a peak of the substantially triangular prism shape and, wherein the substantially triangular prism shape includes opposing facets extending from the corresponding peak to the base layer, and further wherein at least one of the peak and opposing sides of at least one of the microstructures is non-linear in extension along the base layer.
62. The light redirecting film article according to any of the preceding embodiments, wherein each of the microstructures has a substantially triangular prism shape, wherein the primary axis is defined along a peak of the substantially triangular prism shape and, wherein the peak of at least some of the microstructures is rounded.
63. The light redirecting film article according to any of the preceding embodiments, wherein a peak of the substantially triangular prism shape defines an apex angle of about 120°.
64. The light redirecting film article according to any of the preceding embodiments, wherein the microstructures project 5 micrometers-500 micrometers from the base layer.
65. The light redirecting film article according to any of the preceding embodiments, wherein the base layer comprises a polymeric material.
66. The light redirecting film article according to any of the preceding embodiments, wherein the microstructures comprise a polymeric material.
67. The light redirecting film article according to any of the preceding embodiments, wherein the microstructures comprise a polymeric material, and wherein the microstructures comprises the same polymeric material as the base layer.
68. The light redirecting film article according to any of the preceding embodiments, wherein the reflective layer comprises a material coating selected from the group consisting of a metallic material, an inorganic material, and an organic material.
69. The light redirecting film article of according to any of the preceding embodiments, further comprising:

an adhesive adjacent the base layer opposite the microstructures.
70. The light redirecting film article according to any of the preceding embodiments, wherein the light redirecting film is formed as a roll having a roll width of not more than 15.25 cm (6 inches).
71. A PV module, comprising:

a plurality of PV cells electrically connected by tabbing ribbons; and

a light redirecting film article applied over at least a portion of at least one of the tabbing ribbons, the light redirecting film article comprising:

a light redirecting film defining a longitudinal axis and including:
a base layer,
an ordered arrangement of a plurality of microstructures projecting from the base layer,
wherein each of the microstructures extends along the base layer to define a corresponding primary axis,
wherein the primary axis of at least one of the microstructures is oblique with respect to the longitudinal axis,
and further wherein the longitudinal axis and the primary axis of the at least one microstructure define a bias angle, and

a reflective layer over the microstructures opposite the base layer.
72. The PV module according to any of the preceding embodiments directed to a PV module, wherein the at least one tabbing ribbon defines a length direction, and further wherein the light redirecting film article as applied over the at least one tabbing ribbon arranges the primary axis of the at least one microstructure to be oblique with respect to the length direction.
73. The PV module according to any of the preceding embodiments directed to a PV module, further comprising the light redirecting film article applied to at least one additional region that is free of the PV cells.
74. The PV module according to any of the preceding embodiments directed to a PV module, further comprising light redirecting film article applied to the perimeter surrounding at least one of the PV cells.
75. The PV module according to any of the preceding embodiments directed to a PV module, further comprising light redirecting film article applied to an area between an immediately adjacent pair of the PV cells.
76. The PV module according to any of the preceding embodiments directed to a PV module, wherein the PV module exhibits substantially similar annual efficiency performance when installed in a landscape orientation or a portrait orientation.
77. The PV module according to any of the preceding embodiments directed to a PV module, wherein the light redirecting film article has a bias angle in the range of 1° to 90°.
78. The PV module according to any of the preceding embodiments directed to a PV module, wherein the light redirecting film article has a bias angle in the range of 20° to 70°.
79. The PV module according to any of the preceding embodiments directed to a PV module, wherein the bias angle formed between the primary axis and the longitudinal axis of each of the microstructures is in the range of −20° to −70°.
80. The PV module according to any of the preceding embodiments directed to a PV module, wherein the light redirecting film article has a bias angle is 45° plus or minus 2 degrees.
81. The PV module according to any of the preceding embodiments directed to a PV module, wherein the light redirecting film article has a bias angle is −45° plus or minus 2 degrees.
82. The PV module according to any of the preceding embodiments directed to a PV module, wherein the bias angle is from 65° to 90°.
83. The light redirecting film article according to any of the preceding embodiments, wherein the bias angle is from 70° to 90°.
84. The PV module according to any of the preceding embodiments directed to a PV module, wherein the bias angle is from 75° to 90°.
85. The PV module according to any of the preceding embodiments directed to a PV module, wherein the bias angle is from 75° to 85°.
86. The PV module according to any of the preceding embodiments directed to a PV module, wherein the bias angle is from 80° to 90°.
87. The PV module according to any of the preceding embodiments directed to a PV module, wherein the bias angle is from 80° to 85°.
88. The PV module according to any of the preceding embodiments directed to a PV module, wherein the bias angle is 74° plus or minus 2 degrees.
89. The PV module according to any of the preceding embodiments directed to a PV module, wherein the bias angle is 75° plus or minus 2 degrees.
90. The PV module according to any of the preceding embodiments directed to a PV module, wherein the bias angle is 76° plus or minus 2 degrees.
91. The PV module according to any of the preceding embodiments directed to a PV module, wherein the bias angle is 77° plus or minus 2 degrees.
92. The PV module according to any of the preceding embodiments directed to a PV module, wherein the bias angle is 78° plus or minus 2 degrees.
93. The PV module according to any of the preceding embodiments directed to a PV module, wherein the bias angle is 79° plus or minus 2 degrees.
94. The PV module according to any of the preceding embodiments directed to a PV module, wherein the bias angle is 80° plus or minus 2 degrees.
95. The PV module according to any of the preceding embodiments directed to a PV module, wherein the bias angle is 81° plus or minus 2 degrees.
96. The PV module according to any of the preceding embodiments directed to a PV module, wherein the bias angle is 82° plus or minus 2 degrees.
97. The PV module according to any of the preceding embodiments directed to a PV module, wherein the bias angle is 83° plus or minus 2 degrees.
98. The PV module according to any of the preceding embodiments directed to a PV module, wherein the bias angle is 84° plus or minus 2 degrees.
99. The PV module according to any of the preceding embodiments directed to a PV module, wherein the bias angle is 85° plus or minus 2 degrees.
100. The PV module according to any of the preceding embodiments directed to a PV module, wherein the bias angle is 86° plus or minus 2 degrees.
101. The PV module according to any of the preceding embodiments directed to a PV module, wherein the bias angle is 87° plus or minus 2 degrees.
102. The PV module according to any of the preceding embodiments directed to a PV module, wherein the bias angle is 88° plus or minus 2 degrees.
103. The PV module according to any of the preceding embodiments directed to a PV module, wherein the bias angle is 89° plus or minus 2 degrees.
104. The PV module according to any of the preceding embodiments directed to a PV module, wherein the bias angle is 90° plus or minus 2 degrees.
105. The PV module according to any of the preceding embodiments directed to a PV module, wherein the bias angle is from −65° to −90°.
106. The light redirecting film article according to any of the preceding embodiments, wherein the bias angle is from −70° to −90°.
107. The PV module according to any of the preceding embodiments directed to a PV module, wherein the bias angle is from −75° to −90°.
108. The PV module according to any of the preceding embodiments directed to a PV module, wherein the bias angle is from −5° to −85°.
109. The PV module according to any of the preceding embodiments directed to a PV module, wherein the bias angle is from −80° to −90°.
110. The PV module according to any of the preceding embodiments directed to a PV module, wherein the bias angle is from −80° to −85°.
111. The PV module according to any of the preceding embodiments directed to a PV module, wherein the bias angle is −74° plus or minus −2 degrees.
112. The PV module according to any of the preceding embodiments directed to a PV module, wherein the bias angle is −75° plus or minus −2 degrees.
113. The PV module according to any of the preceding embodiments directed to a PV module, wherein the bias angle is −76° plus or minus 2 degrees.
114. The PV module according to any of the preceding embodiments directed to a PV module, wherein the bias angle is −77° plus or minus 2 degrees.
115. The PV module according to any of the preceding embodiments directed to a PV module, wherein the bias angle is −78° plus or minus 2 degrees.
116. The PV module according to any of the preceding embodiments directed to a PV module, wherein the bias angle is −79° plus or minus 2 degrees.
117. The PV module according to any of the preceding embodiments directed to a PV module, wherein the bias angle is −80° plus or minus 2 degrees.
118. The PV module according to any of the preceding embodiments directed to a PV module, wherein the bias angle is −81° plus or minus 2 degrees.
119. The PV module according to any of the preceding embodiments directed to a PV module, wherein the bias angle is −82° plus or minus 2 degrees.
120. The PV module according to any of the preceding embodiments directed to a PV module, wherein the bias angle is −83° plus or minus 2 degrees.
121. The PV module according to any of the preceding embodiments directed to a PV module, wherein the bias angle is −84° plus or minus 2 degrees.
122. The PV module according to any of the preceding embodiments directed to a PV module, wherein the bias angle is −85° plus or minus 2 degrees.
123. The PV module according to any of the preceding embodiments directed to a PV module, wherein the bias angle is −86° plus or minus 2 degrees.
124. The PV module according to any of the preceding embodiments directed to a PV module, wherein the bias angle is −87° plus or minus 2 degrees.
125. The PV module according to any of the preceding embodiments directed to a PV module, wherein the bias angle is 88° plus or minus 2 degrees.
126. The PV module according to any of the preceding embodiments directed to a PV module, wherein the bias angle is −89° plus or minus 2 degrees.
127. The PV module according to any of the preceding embodiments directed to a PV module, wherein the bias angle is −90° plus or minus 2 degrees.
128. A method of making a PV module including a plurality of PV cells electrically connected by tabbing ribbons, the method comprising:

applying a light redirecting film article over at least a portion of at least one of the tabbing ribbons, the light redirecting film article comprising:

a light redirecting film defining a longitudinal axis and including:
a base layer,
an ordered arrangement of a plurality of microstructures projecting from the base layer,
wherein each of the microstructures extends along the base layer to define a corresponding primary axis,
wherein the primary axis of at least one of the microstructures is oblique with respect to the longitudinal axis,
and further wherein the longitudinal axis and the primary axis of the at least one microstructure define a bias angle, and

a reflective layer over the microstructures opposite the base layer.
129. The method according to any of the preceding embodiments directed to methods of making a PV module, further comprising:

applying a length of the light redirecting film article to a region between immediately adjacent PV cells.
130. The method of according to any of the preceding embodiments directed to methods of making a PV module, further comprising:

applying a length of the light redirecting film article about a perimeter of at least one of the PV cells.
131. A method of installing a PV module at an installation site, the PV module including a plurality of spaced apart PV cells arranged to define regions of the PV module that are free of PV cells, the method comprising:

applying a first light redirecting film article over at least a portion of one of the regions free of PV cells, the first light redirecting film article including:

a light redirecting film defining a longitudinal axis and including:
a base layer,
an ordered arrangement of a plurality of microstructures projecting from the base layer,
wherein each of the microstructures extends along the base layer to define a corresponding primary axis,
and further wherein the primary axis of at least one of the microstructures is oblique with respect to the longitudinal axis, and
a reflective layer over the microstructures opposite the base layer; and mounting the PV module at the installation site;

wherein following the step of mounting, the primary axis of the at least one microstructure is substantially aligned with an East-West direction of the installation site.
132. The method according to any of the preceding embodiments directed to methods of installing a PV module, wherein following the step of applying the light redirecting film, a front-side layer is disposed over the PV cells in completing the PV module.
133. The method according to any of the preceding embodiments directed to methods of installing a PV module, wherein following the step of mounting, the primary axis of the at least one microstructure defines an angle with respect to the East-West direction of no more than 45 degrees.
134. The method according to any of the preceding embodiments directed to methods of installing a PV module, wherein following the step of mounting, the primary axis of the at least one microstructure defines an angle with respect to the East-West direction of no more than 20 degrees.
135. The method according to any of the preceding embodiments directed to methods of installing a PV module, wherein following the step of mounting, the primary axis of the at least one microstructure defines an angle with respect to the East-West direction of no more than 5 degrees.
136. The method according to any of the preceding embodiments directed to methods of installing a PV module, wherein the PV module defines a length direction and a width direction, and further wherein the light redirecting film article is disposed between two immediately adjacent PV cells and extends in the length direction.
137. The method according to any of the preceding embodiments directed to methods of installing a PV module, wherein the PV module defines a length direction and a width direction, and further wherein the light redirecting film article is disposed between two immediately adjacent PV cells and extends in the width direction.
138. The method according to any of the preceding embodiments directed to methods of installing a PV module, further comprising:

applying a second light redirecting film article over at least a portion of a second one of the regions free of the PV cells, the second light redirecting film article including:

a light redirecting film defining a longitudinal axis and including:
a base layer,
an ordered arrangement of a plurality of microstructures projecting from the base layer,
wherein each of the microstructures extends along the base layer to define a corresponding primary axis,
and further wherein the primary axis of at least one of the microstructures is oblique with respect to the longitudinal axis, and

a reflective layer over the microstructures opposite the base layer;

wherein the first and second light redirecting film articles extend in differing directions relative to a perimeter shape of the PV module;

and further wherein following the step of mounting, the primary axis of the at least one microstructure of the second light redirecting film article is substantially aligned with the East-West direction of the installation site.
139. The method of embodiment 88, wherein a bias angle of the at least one microstructure of the first light redirecting film article differs from a bias angle of the at least one microstructure of the second light redirecting film article.
140. A solar panel, comprising:

a plurality of PV cells electrically connected by tabbing ribbons; and

a light redirecting film article applied over at least one region that is free of the PV cells, the light redirecting film article comprising:

a light redirecting film defining a longitudinal axis and including:
a base layer,
an ordered arrangement of a plurality of microstructures projecting from the base layer,
wherein each of the microstructures extends along the base layer to define a corresponding primary axis,
wherein the primary axis of at least one of the microstructures is oblique with respect to the longitudinal axis,
and further wherein the longitudinal axis and the primary axis of the at least one microstructure define a bias angle, and

a reflective layer over the microstructures opposite the base layer.
141. The solar panel according to any of the preceding embodiments directed to a solar panel, wherein the at least one tabbing ribbon defines a length direction, and further wherein the light redirecting film article applied over the at least one region that is free of the PV cells arranges the primary axis of the at least one microstructure to be oblique with respect to the length direction.
142. The solar panel according to any of the preceding embodiments directed to a solar panel, wherein the at least one region that is free of the PV cells is a perimeter of at least one of the PV cells.
143. The solar panel according to any of the preceding embodiments directed to a solar panel, wherein the at least one region that is free of the PV cells is an area between an immediately adjacent pair of the PV cells.
144. The solar panel according to any of the preceding embodiments directed to a solar panel, wherein the solar panel exhibits substantially similar annual efficiency performance when installed in a landscape orientation or a portrait orientation.
145. The solar panel according to any of the preceding embodiments directed to a solar panel, wherein the bias angle in the range of 1° to 90°.
146. The solar panel according to any of the preceding embodiments directed to a solar panel, wherein the bias angle in the range of 20° to 70°.
147. The solar panel according to any of the preceding embodiments directed to a solar panel, wherein the bias angle in the range of −20° to −70°.
148. The solar panel according to any of the preceding embodiments directed to a solar panel, wherein the bias angle is 45° plus or minus 2 degrees.
149. The solar panel according to any of the preceding embodiments directed to a solar panel, wherein the bias angle is from 65° to 90°.
150. The solar panel according to any of the preceding embodiments directed to a solar panel, wherein the bias angle is from 70° to 90°.
151. The solar panel according to any of the preceding embodiments directed to a solar panel, wherein the bias angle is from 75° to 90°.
152. The solar panel according to any of the preceding embodiments directed to a solar panel, wherein the bias angle is from 75° to 85°.
153. The solar panel according to any of the preceding embodiments directed to a solar panel, wherein the bias angle is from 80° to 90°.
154. The solar panel according to any of the preceding embodiments directed to a solar panel, wherein the bias angle is from 80° to 85°.
155. The solar panel according to any of the preceding embodiments directed to a solar panel, wherein the bias angle is 74° plus or minus 2 degrees.
156. The solar panel according to any of the preceding embodiments directed to a solar panel, wherein the bias angle is 75° plus or minus 2 degrees.
157. The solar panel according to any of the preceding embodiments directed to a solar panel, wherein the bias angle is 76° plus or minus 2 degrees.
158. The solar panel according to any of the preceding embodiments directed to a solar panel, wherein the bias angle is 77° plus or minus 2 degrees.
159. The solar panel according to any of the preceding embodiments directed to a solar panel, wherein the bias angle is 78° plus or minus 2 degrees.
160. The solar panel according to any of the preceding embodiments directed to a solar panel, wherein the bias angle is 79° plus or minus 2 degrees.
161. The solar panel according to any of the preceding embodiments directed to a solar panel, wherein the bias angle is 80° plus or minus 2 degrees.
162. The solar panel according to any of the preceding embodiments directed to a solar panel, wherein the bias angle is 81° plus or minus 2 degrees.
163. The solar panel according to any of the preceding embodiments directed to a solar panel, wherein the bias angle is 82° plus or minus 2 degrees.
164. The solar panel according to any of the preceding embodiments directed to a solar panel, wherein the bias angle is 83° plus or minus 2 degrees.
165. The solar panel according to any of the preceding embodiments directed to a solar panel, wherein the bias angle is 84° plus or minus 2 degrees.
166. The solar panel according to any of the preceding embodiments directed to a solar panel, wherein the bias angle is 85° plus or minus 2 degrees.
167. The solar panel according to any of the preceding embodiments directed to a solar panel, wherein the bias angle is 86° plus or minus 2 degrees.
168. The solar panel according to any of the preceding embodiments directed to a solar panel, wherein the bias angle is 87° plus or minus 2 degrees.
169. The solar panel according to any of the preceding embodiments directed to a solar panel, wherein the bias angle is 88° plus or minus 2 degrees.
170. The solar panel according to any of the preceding embodiments directed to a solar panel, wherein the bias angle is 89° plus or minus 2 degrees.
171. The solar panel according to any of the preceding embodiments directed to a solar panel, wherein the bias angle is 90° plus or minus 2 degrees.
172. The solar panel according to any of the preceding embodiments directed to a solar panel, wherein the bias angle in the range of 1° to 90°.
173. The solar panel according to any of the preceding embodiments directed to a solar panel, wherein the bias angle in the range of 20° to 70°.
174. The solar panel according to any of the preceding embodiments directed to a solar panel, wherein the bias angle in the range of −20° to −70°.
175. The solar panel according to any of the preceding embodiments directed to a solar panel, wherein the bias angle is −45° plus or minus 2 degrees.
176. The solar panel according to any of the preceding embodiments directed to a solar panel, wherein the bias angle is from −65° to −90°.
177. The solar panel according to any of the preceding embodiments directed to a solar panel, wherein the bias angle is from −70° to −90°.
178. The solar panel according to any of the preceding embodiments directed to a solar panel, wherein the bias angle is from −75° to −90°.
179. The solar panel according to any of the preceding embodiments directed to a solar panel, wherein the bias angle is from −75° to −85°.
180. The solar panel according to any of the preceding embodiments directed to a solar panel, wherein the bias angle is from −80° to −90°.
181. The solar panel according to any of the preceding embodiments directed to a solar panel, wherein the bias angle is from −80° to −85°.
182. The solar panel according to any of the preceding embodiments directed to a solar panel, wherein the bias angle is −74° plus or minus 2 degrees.
183. The solar panel according to any of the preceding embodiments directed to a solar panel, wherein the bias angle is −75° plus or minus 2 degrees.
184. The solar panel according to any of the preceding embodiments directed to a solar panel, wherein the bias angle is −76° plus or minus 2 degrees.
185. The solar panel according to any of the preceding embodiments directed to a solar panel, wherein the bias angle is −77° plus or minus 2 degrees.
186. The solar panel according to any of the preceding embodiments directed to a solar panel, wherein the bias angle is −78° plus or minus 2 degrees.
187. The solar panel according to any of the preceding embodiments directed to a solar panel, wherein the bias angle is −79° plus or minus 2 degrees.
188. The solar panel according to any of the preceding embodiments directed to a solar panel, wherein the bias angle is −80° plus or minus 2 degrees.
189. The solar panel according to any of the preceding embodiments directed to a solar panel, wherein the bias angle is −81° plus or minus 2 degrees.
190. The solar panel according to any of the preceding embodiments directed to a solar panel, wherein the bias angle is −82° plus or minus 2 degrees.
191. The solar panel according to any of the preceding embodiments directed to a solar panel, wherein the bias angle is −83° plus or minus 2 degrees.
192. The solar panel according to any of the preceding embodiments directed to a solar panel, wherein the bias angle is −84° plus or minus 2 degrees.
193. The solar panel according to any of the preceding embodiments directed to a solar panel, wherein the bias angle is −85° plus or minus 2 degrees.
194. The solar panel according to any of the preceding embodiments directed to a solar panel, wherein the bias angle is −86° plus or minus 2 degrees.
195. The solar panel according to any of the preceding embodiments directed to a solar panel, wherein the bias angle is −87° plus or minus 2 degrees.
196. The solar panel according to any of the preceding embodiments directed to a solar panel, wherein the bias angle is −88° plus or minus 2 degrees.
197. The solar panel according to any of the preceding embodiments directed to a solar panel, wherein the bias angle is −89° plus or minus 2 degrees.
198. The solar panel according to any of the preceding embodiments directed to a solar panel, wherein the bias angle is −90° plus or minus 2 degrees.

### EXAMPLES

The present invention is more particularly described in the following examples that are intended as illustrations only, since numerous modifications and variations within the scope of the present invention will be apparent to those skilled in the art.

A number of light redirecting films were made by extrusion replication of polycarbonate. The optical properties of the resulting light redirecting films were then analyzed using an Eldim EZContrast L80 instrument (Eldim S. A., Hérouville-Saint-Clair, France) with collimated beam reflective option. The angle of the light input for the measurements was representative of angles for which stray light reflection is considered the worst. In addition to the measurements taken on each light redirecting film sample, the same example light redirecting films were modeled using a ray tracing program. The angles of the input light used in the models were representative of angles for which stray light reflection is considered the worst. The output light angles were collected from each model and plotted in a luminance conoscopic image.

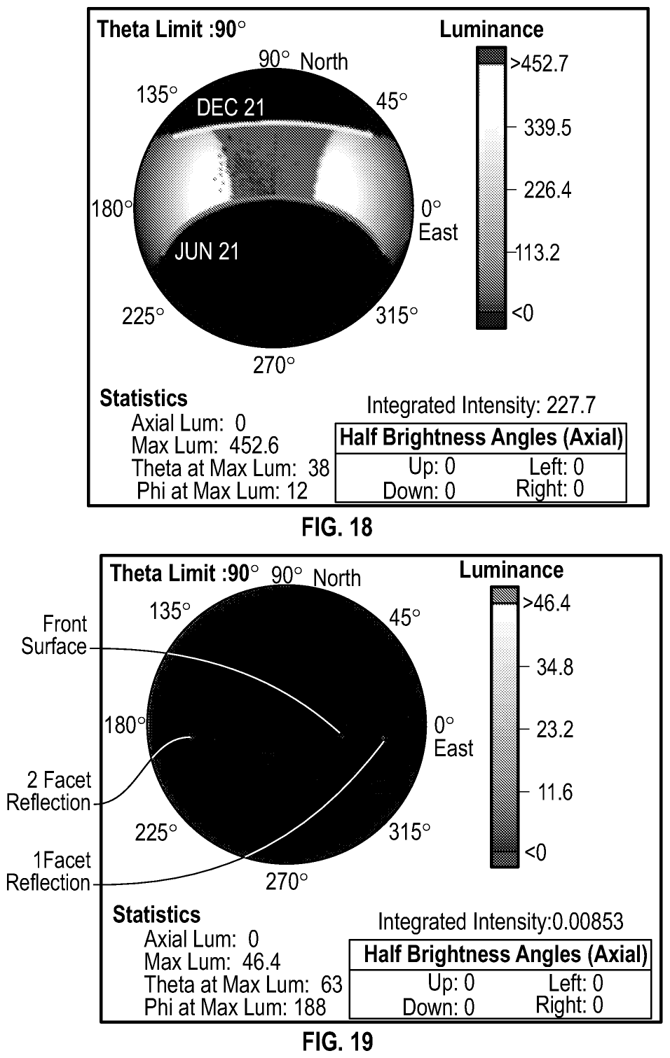

Stray light reflects from photovoltaic modules using light redirecting films during certain times of the day. The amount of stray light reflected depends on the latitude of the installation, the orientation of the photovoltaic module, the tilt of the module, the time of day, and the time of year. At 30° north latitude, a south-facing photovoltaic module with 10° tilt toward the equator in portrait mode (such that the light redirecting film prisms run north-south), light striking the light redirecting films is contained within angles of total internal reflection (TIR) primarily during mid-day hours. At other times, some of the reflected light escapes the module at discrete angles. FIG. 18 illustrates an example conoscopic plot depicting input angles for light that escapes from the photovoltaic module over the course of the year from a ray trace simulation. In the plot, 0° is east and 90° is north. The locus of angles for June 21 and December 21 are shown by the pair of curved lines, labeled accordingly in FIG. 18. Reflected irradiance values are shown in the legend. Black points near the center of the plot correspond to missing data from data sampling.

FIG. 19 illustrates a conoscopic plot depicting the simulated reflected angles from June 21 at 9:21 a.m. This is the time of day and year that exhibits the strongest reflection for 30° north latitude for a south-facing photovoltaics module with 10° module tilt. In FIG. 19, the light at each angle is contained within a single point due to the specular nature of the prism facets. The intent of the disclosed examples of light redirecting films is to provide a modest diffusion of the light reflected by the photovoltaics module. A modest diffusion of the light reflected from the photovoltaics module (for example, ±1° diffusion) can spread the reflected light in such a way as to decrease the radiance of this stray light by a factor of 25. At this weak level of diffusion, normal angle light will still undergo total internal reflection.

### Example 1

### Flat Prisms with Chaos

A master tool was generated by a fast tool servo (FTS) system and method as described in U.S. Publication No. 2003/0035231 (Epstein et al.). Using this method, commands controlling the depth of the cutting tool connected to the FTS were generated by a chaotic (i.e., pseudo-random) algorithm, causing grooves of randomly varying depth to be cut into a master tool cylinder.

A microstructured film was fabricated using the master tool as described in U.S. Pat. No. 6,758,992 (Solomon, et al.) by forcing a molten thermoplastic polymer resin (e.g., Sabic Lexan™ HFD1910 Polycarbonate heated to 540 F) between the master tool cylinder and a second flat roller to create a film with positive structures corresponding to the chaotic negative features of the master tool. This resulted in a sample film with prisms featuring flat facets but for which the prism peaks vary in height continuously down web in a single prism and vary in height discontinuously from prism to prism. A reflective coating was applied to the microprisms in a manner similar to that described in U.S. Pat. No. 4,307,150 (Roche et al.). An opaque specular metallic surface was vapor coated onto the microprisms using high purity (99.88+%) aluminum.

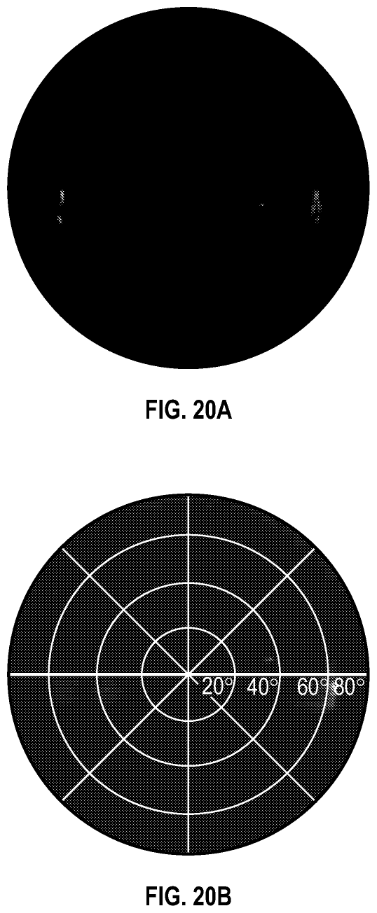

The resulting light redirecting film was integrated into a single cell solar module including front glass, EVA encapsulant, silicon solar cell, and white backsheet. The single cell module was analyzed using the Eldim EZContrast L80 instrument with collimated beam reflective option. This instrument illuminates a sample using a narrow angle source while collecting the reflected light for analysis of its angular distribution. The input light source was arranged to coincide with the angle corresponding to June 21 at 9:21 a.m. for a south-facing module located at 30° north latitude and 10° module tilt. A conoscopic image (shown as FIG. 20A) was created from ray tracing simulations using a 3M proprietary ray tracing code, surfaces and materials of a photovoltaic module were assembled to create an optical model corresponding to the sample film. The analysis can be performed, however, using commercially available software, such as TracePro from Lambda Research Corporation, Littleton, Mass. A conoscopic image (shown as FIG. 20B) was created the output of the Eldim instrument, and this image was compared to the conoscopic image of FIG. 19, showing reflected angles from flat facet prisms of consistent prism height. The results for the flat-faceted prisms with varying (chaotic) prism heights indicated a slight tangential spread of the reflected angles over standard flat facets with consistent height. Simulation results predict a tangential spread of the stray light from the single facet interaction of 14° and a spread of 14° for the double facet interaction. Measurements confirm a tangential spread of the light with some slight radial spread. The single facet interaction was diffused 12° tangentially and 6° radially and 16° tangentially and 11° radially for the double facet interaction.

### Example 2

### Curved Prisms with Chaos

A master tool was generated by a fast tool servo (FTS) system and method. Using this method, commands controlling the depth of the cutting tool connected to the FTS were generated by a chaotic (i.e., pseudo-random) algorithm, causing grooves of randomly varying depth to be cut into a master tool cylinder. In addition, the head of the cutting tool had slightly curved sides, causing the sides or facets of the resulting grooves to have a slight curve (e.g., approximately 1 degree of curvature).

A microstructured film was fabricated using the master tool by forcing a molten thermoplastic polymer resin (e.g., Sabic Lexan™ HFD1910 Polycarbonate heated to 540 F) between the master tool cylinder and a second flat roller to create a film with positive structures corresponding to the chaotic negative features of the master tool. This resulted in a sample film with prisms featuring curved facets but for which the prism peaks vary in height continuously down web in a single prism and vary in height discontinuously from prism to prism. A reflective coating was applied to the. An opaque specular metallic surface was vapor coated onto the microprisms using high purity (99.88+%) aluminum.

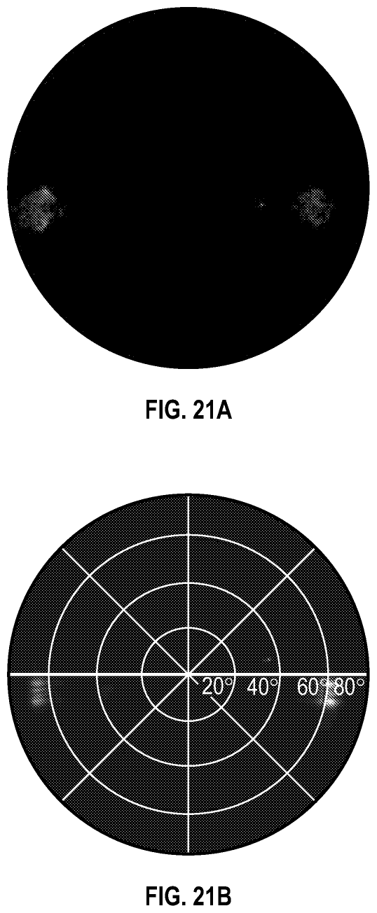

The resulting light redirecting film was integrated into a single cell solar module including front glass, EVA encapsulant, silicon solar cell, and white backsheet. The single cell module was analyzed using the Eldim EZContrast L80 instrument with collimated beam reflective option. The input light source was arranged to coincide with the angle corresponding to June 21 at 9:21 a.m. for a south-facing module located at 30° north latitude and 10° module tilt. A conoscopic image (FIG. 21A) was created from ray tracing simulations using a 3M proprietary ray tracing code, surfaces and materials of a photovoltaic module were assembled to create an optical model corresponding to the sample film. A conoscopic image (shown as FIG. 21B) was created the output of the Eldim instrument, and this image was compared to the conoscopic image of FIG. 19, showing reflected angles from flat facet prisms of consistent prism height. The results for the curve-faceted prisms with varying (chaotic) prism heights indicated a two-dimensional spread of the reflected angles over standard flat facets with consistent height. Simulation results predict a 2-dimensional spread of the stray light from the single facet interaction of 17° tangentially and 18° radially and a spread of 16° tangentially and 18° radially for the double facet interaction. Measurements confirm a tangential spread of the light. The single facet interaction was diffused to 8° tangentially and 13° radially and 16° tangentially and 14° radially for the double facet interaction.

### Example 3

### Curved Prisms

A master tool was generated by a fly-cutting system and method as described in U.S. Pat. No. 8,443,704 (Burke et al.) and U.S. Publication No. 2009/0038450 (Campbell et al.). Using this method, grooves of consistent depth featuring curved facets (e.g., approximately 1 degree of curvature). were generated.

A microstructured film was fabricated using the master tool by forcing a molten thermoplastic polymer resin (e.g., Sabic Lexan™ HFD1910 Polycarbonate heated to 540 F) between the master tool cylinder and a second flat roller to create a film with positive structures corresponding to the negative features of the master tool. This resulted in a sample film with prisms featuring curved facets and consistent prism to prism height measurements. A reflective coating was applied to the microprisms. An opaque specular metallic surface was vapor coated onto the microprisms using high purity (99.88+%) aluminum.

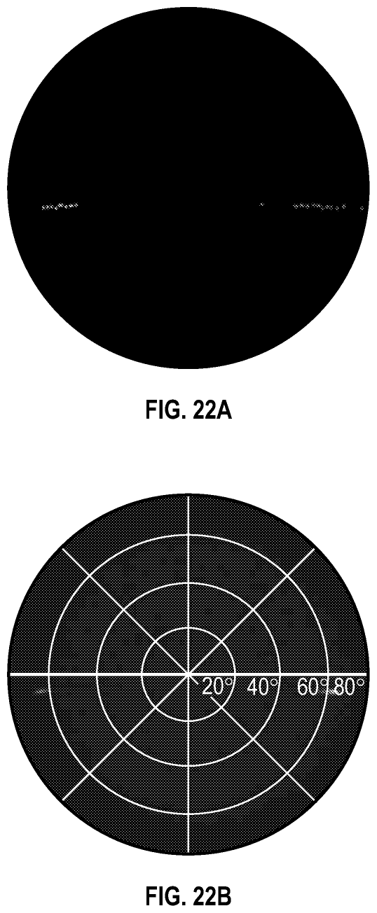

The resulting light redirecting film was integrated into a single cell solar module including front glass, EVA encapsulant, silicon solar cell, and white backsheet. The single cell module was analyzed using the Eldim EZContrast L80 instrument with collimated beam reflective option. The input light source was arranged to coincide with the angle corresponding to June 21 at 9:21 a.m. for a south-facing module located at 30° north latitude and 10° module tilt. A conoscopic image (FIG. 22A) was created from ray tracing simulations using a 3M proprietary ray tracing code, surfaces and materials of a photovoltaic module were assembled to create an optical model corresponding to the sample film. A conoscopic image (shown as FIG. 22B) was created the output of the Eldim instrument, and this image was compared to the conoscopic image of FIG. 19, showing reflected angles from flat facet prisms of consistent prism height. The results for the curve-faceted prisms with consistent prism heights indicated a radial spread of the reflected angles over standard flat facets with consistent height. Simulation results predict a radial spread of the stray light from the single facet interaction of 6° and a spread of 12° for the double facet interaction. Measurements confirm a radial spread of the light. The single facet interaction was diffused 9° and 12° for the double facet interaction.

### Example 4

### Curved Prisms with 45-Degree Bias (Simulation)

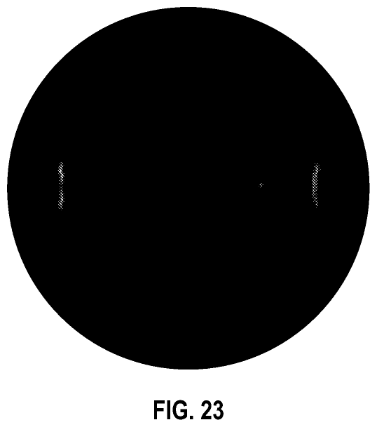

A conoscopic image (FIG. 23) was created from ray tracing simulations of a film with curved facets positioned with a 45-degree bias angle using a 3M proprietary ray tracing code. Surfaces and materials of a photovoltaic module were assembled to create an optical model corresponding to a sample film with curved facets at a 45-degree bias. The results for the curve-faceted prisms with a 45-degree bias indicated a diffused, tangential spread of the reflected angles over standard flat facets with consistent height. Simulation results predict a 2-dimensional spread of the stray light from the single facet interaction of 9° and a spread of 21° tangentially for the double facet interaction.

1. A light redirecting film article comprising a light redirecting film,
wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
wherein at least one of the microstructures extends along the base layer to define a primary longitudinal axis,
wherein at least one microstructure comprises a prism having a height and a peak,
wherein the height of the prism is defined by the distance from the first major surface of the base layer to the peak of the prism,
wherein the peak defines a ridgeline in the direction of the primary longitudinal axis,
wherein the height of the prism is not constant along the ridgeline.

2-4. (canceled)

5. A light redirecting film article comprising a light redirecting film,
wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
wherein at least one of the microstructures extends along the base layer to define a primary longitudinal axis,
wherein at least one microstructure comprises a prism having a height and a peak,
wherein the height of the prism is defined by the distance from the first major surface of the base layer to the peak of the prism,
wherein the peak defines a ridgeline in the direction of the primary longitudinal axis,
wherein the length of the light redirecting film defines a film longitudinal axis, wherein the primary longitudinal axis of at least a portion of the microstructures is oblique with respect to the film longitudinal axis defining a non-zero bias angle.

6-9. (canceled)

10. A light redirecting film article comprising a light redirecting film,
wherein the light redirecting film comprises:
a base layer having a first major surface and a second major surface opposite the first major surface;
an ordered arrangement of a plurality of microstructures projecting from the second major surface of the base layer; and
a reflective layer adjacent the microstructures opposite the base layer,
wherein at least one of the microstructures extends along the base layer to define a primary longitudinal axis,
wherein at least one microstructure comprises a prism having a height and a peak,
wherein the height of the prism is defined by the distance from the first major surface of the base layer to the peak of the prism,
wherein the peak defines a ridgeline in the direction of the primary longitudinal axis,
wherein the height of the prism is not constant along the ridgeline, and
wherein the length of the light redirecting film defines a film longitudinal axis, wherein the primary longitudinal axis of at least a portion of the microstructures is oblique with respect to the film longitudinal axis defining a non-zero bias angle.

11-17. (canceled)

18. The light redirecting film article according to claim 1, wherein the length of the light redirecting film defines a film longitudinal axis, wherein the primary longitudinal axis of a first portion of the microstructures is oblique with respect to the film longitudinal axis defining a first bias angle, wherein the primary longitudinal axis of a second portion of the microstructures is oblique with respect to the film longitudinal axis defining a second bias angle, and wherein the first bias angle is not the same as the second bias angle.

19. The light redirecting film article according to claim 5, wherein at least one facet of at least one microstructure is curved.

20-31. (canceled)

32. The light redirecting film article according to claim 1, wherein the light directing film comprises a strip having opposing end edges and opposing side edges, a length of the strip being defined between the opposing end edges and a width of the strip being defined between the opposing side edges, and further wherein the length is at least 10× the width, and even further wherein the longitudinal axis is in a direction of the length.

33-35. (canceled)

36. The light redirecting film article according to claim 1, wherein each of the microstructures has a substantially triangular prism shape, wherein the primary axis is defined along a peak of the substantially triangular prism shape and, wherein the peak of at least some of the microstructures is rounded.

37-40. (canceled)

41. The light redirecting film article according to claim 1, wherein the microstructures comprise a polymeric material, and wherein the microstructures comprise comprises the same polymeric material as the base layer.

42. (canceled)

43. The light redirecting film article according to claim 1, further comprising:
an adhesive adjacent the base layer opposite the microstructures.

44. (canceled)

45. A PV module comprising a plurality of PV cells electrically connected by tabbing ribbons, and including a light redirecting film article according to claim 1.

46-50. (canceled)

51. The light redirecting film article according to claim 5, wherein the microstructures comprise a polymeric material, and wherein the microstructures comprise the same polymeric material as the base layer.

52. The light redirecting film article according to claim 5, wherein the light directing film comprises a strip having opposing end edges and opposing side edges, a length of the strip being defined between the opposing end edges and a width of the strip being defined between the opposing side edges, and further wherein the length is at least 10× the width, and even further wherein the longitudinal axis is in a direction of the length.

53. The light redirecting film article according to claim 5, wherein each of the microstructures has a substantially triangular prism shape, wherein the primary axis is defined along a peak of the substantially triangular prism shape and, wherein the peak of at least some of the microstructures is rounded.

54. The light redirecting film article according to claim 5, further comprising:
an adhesive adjacent the base layer opposite the microstructures.

55. A PV module comprising a plurality of PV cells electrically connected by tabbing ribbons, and including a light redirecting film article according to claim 5.

56. The light redirecting film article according to claim 10, wherein the microstructures comprise a polymeric material, and wherein the microstructures comprise the same polymeric material as the base layer.

57. The light redirecting film article according to claim 10, wherein the light directing film comprises a strip having opposing end edges and opposing side edges, a length of the strip being defined between the opposing end edges and a width of the strip being defined between the opposing side edges, and further wherein the length is at least 10× the width, and even further wherein the longitudinal axis is in a direction of the length.

58. The light redirecting film article according to claim 10, wherein each of the microstructures has a substantially triangular prism shape, wherein the primary axis is defined along a peak of the substantially triangular prism shape and, wherein the peak of at least some of the microstructures is rounded.

59. The light redirecting film article according to claim 10, further comprising:
an adhesive adjacent the base layer opposite the microstructures.

60. A PV module comprising a plurality of PV cells electrically connected by tabbing ribbons, and including a light redirecting film article according to claim 10.
